(19) United States
(12) Patent Application Publication
(10) Pub. No.: US 2026/0020364 A1
(43) Pub. Date: Jan. 15, 2026

(54) PHOTODETECTION DEVICE AND ELECTRONIC DEVICE

(71) Applicant: SONY SEMICONDUCTOR SOLUTIONS CORPORATION, KANAGAWA (JP)

(72) Inventors: ATSUSHI TODA, KANAGAWA (JP); SHINICHIRO NOUDO, KANAGAWA (JP); YOSHIAKI MASUDA, KANAGAWA (JP)

(21) Appl. No.: 18/993,011

(22) PCT Filed: Jul. 24, 2023
(86) PCT No.: PCT/JP2023/026961

§ 371 Date: Jan. 10, 2025

(30) Foreign Application Priority Data
Aug. 3, 2022 (JP) 2022-124068

(51) Int. Cl. H10F 39/00; G02B 5/28

(52) U.S. Cl. CPC H10F 39/8063; H10F 39/807; G02B 5/281

(57) ABSTRACT

A photodetection device in which flare is suppressed is provided. The photodetection device includes a semiconductor layer in which one surface is a light incident surface and another surface is an element formation surface, the semiconductor layer including a plurality of photoelectric conversion regions arranged in an array along a row direction and a column direction perpendicular to a thickness direction and a multilayer film filter provided integrally with the semiconductor layer on a side of the light incident surface of the semiconductor layer and provided at a position overlapping the photoelectric conversion regions, in which a side of the light incident surface of the photoelectric conversion regions has an uneven shape, and the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.

### TECHNICAL FIELD

The present technology (technology according to the present disclosure) relates to a photodetection device and an electronic device, and particularly relates to a photodetection device having a filter and an electronic device.

### BACKGROUND ART

Conventionally, in a photodetection device, a light shielding film is provided at a pixel boundary in order to suppress flare (for example, Patent Document 1).

### CITATION LIST

### Patent Document Patent Document 1: Japanese Patent Application Laid-Open No. 2014-7427 A

### SUMMARY OF THE INVENTION

### Problems to be Solved by the Invention

In Patent Document 1, in a photodetection device that detects red (R), green (G), and blue (B) light, a light shielding film is provided at a pixel boundary in order to suppress flare. An object of the present technology is to provide a photodetection device and an electronic device in which flare is suppressed.

### Solutions to Problems

A photodetection device according to an aspect of the present technology includes a semiconductor layer in which one surface is a light incident surface and another surface is an element formation surface, the semiconductor layer including a plurality of photoelectric conversion regions arranged in an array along a row direction and a column direction perpendicular to a thickness direction, and a multilayer film filter provided integrally with the semiconductor layer on a side of the light incident surface of the semiconductor layer and provided at a position overlapping the photoelectric conversion regions, in which a side of the light incident surface of the photoelectric conversion regions has an uneven shape, and the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.

An electronic device according to an aspect of the present technology includes a photodetection device, and an optical system that forms an image of image light from a subject on the photodetection device, in which the photodetection device includes a semiconductor layer in which one surface is a light incident surface and another surface is an element formation surface, the semiconductor layer including a plurality of photoelectric conversion regions arranged in an array along a row direction and a column direction perpendicular to a thickness direction, and a multilayer film filter provided integrally with the semiconductor layer on a side of the light incident surface of the semiconductor layer and provided at a position overlapping the photoelectric conversion regions, in which a side of the light incident surface of the photoelectric conversion regions has an uneven shape, and the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.

### BRIEF DESCRIPTION OF DRAWINGS

FIG. 1 is a chip layout diagram illustrating a configuration example of a photodetection device according to a first embodiment of the present technology.

FIG. 2 is a block diagram illustrating a configuration example of the photodetection device according to the first embodiment of the present technology.

FIG. 3 is an equivalent circuit diagram of pixels of the photodetection device according to the first embodiment of the present technology.

FIG. 4 is a longitudinal cross-sectional view illustrating a cross-sectional structure of pixels of the photodetection device according to the first embodiment of the present technology.

FIG. 5 is a transverse cross-sectional view illustrating a planar configuration of an uneven shape when viewed in a cross section taken along line A-A in FIG. 4.

FIG. 6 is a longitudinal cross-sectional view illustrating a cross-sectional structure of a multilayer film filter included in the photodetection device according to the first embodiment of the present technology.

FIG. 7 is a graph illustrating transmittance spectral characteristics of the multilayer film filter according to the first embodiment of the present technology.

FIG. 8 is a longitudinal cross-sectional view illustrating a cross-sectional structure of a pixel of a photodetection device having no uneven shape.

FIG. 9 is a longitudinal cross-sectional view illustrating a cross-sectional structure of a pixel of a photodetection device according to Modification 1 of the first embodiment of the present technology.

FIG. 10 is a transverse cross-sectional view illustrating a planar configuration of an uneven shape according to a modification 1 of the first embodiment of the present technology.

FIG. 11 is a transverse cross-sectional view illustrating a planar configuration of an uneven shape according to a modification 2 of the first embodiment of the present technology.

FIG. 12 is a transverse cross-sectional view illustrating a planar configuration of an uneven shape according to Modification 3 of the first embodiment of the present technology.

FIG. 13 is a transverse cross-sectional view illustrating a planar configuration of an uneven shape according to a modification 4 of the first embodiment of the present technology.

FIG. 14 is a chip layout diagram illustrating a configuration example of a photodetection device according to a second embodiment of the present technology.

FIG. 15 is a longitudinal cross-sectional view illustrating a cross-sectional structure of a pixel of the photodetection device according to the second embodiment of the present technology.

FIG. 16 is a plan view of an optical element layer and an optical element included in the photodetection device according to the second embodiment of the present technology.

FIG. 17A is an enlarged plan view illustrating the optical element included in the photodetection device according to the second embodiment of the present technology.

FIG. 17B is an enlarged longitudinal sectional view illustrating the optical element included in the photodetection device according to the second embodiment of the present technology.

FIG. 17C is an enlarged longitudinal sectional view illustrating the optical element included in the photodetection device according to the second embodiment of the present technology.

FIG. 18 is a plan view of an optical element layer and an optical element included in a photodetection device according to Modification 1 of the second embodiment of the present technology.

FIG. 19 is a plan view of an optical element layer and an optical element included in a photodetection device according to Modification 2 of the second embodiment of the present technology.

FIG. 20 is a plan view of an optical element included in a photodetection device according to Modification 3 of the second embodiment of the present technology.

FIG. 21 is a longitudinal cross-sectional view illustrating a cross-sectional structure of a pixel of a photodetection device according to Modification 4 of the second embodiment of the present technology.

FIG. 22 is a longitudinal cross-sectional view illustrating a cross-sectional structure of a pixel of a photodetection device according to Modification 5 of the second embodiment of the present technology.

FIG. 23 is a block diagram illustrating an example of a schematic configuration of an electronic device according to a third embodiment of the present technology.

### MODE FOR CARRYING OUT THE INVENTION

Hereinafter, preferred embodiments for carrying out the present technology will be described with reference to the drawings. Note that, embodiments hereinafter described each illustrate an example of a representative embodiment of the present technology, and the scope of the present technology is not narrowed by them.

In the following drawings, the same or similar parts are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it is needless to say that the drawings include portions having different dimensional relationships and ratios. In addition, since the drawings suitable for describing the present technology are adopted, there may be a difference in configuration between the drawings.

Furthermore, the embodiments described below each relate to an example of a device or a method for embodying the technical idea of the present technology, and the technical idea of the present technology does not limit the materials, shapes, structures, layouts, and the like of the components to those described below. Various changes can be made to the technical idea of the present technology within the technical scope defined by the claims disclosed in the claims.

The description will be given in the following order.
1. First Embodiment
2. Second Embodiment
3. Third Embodiment

### First Embodiment

In this embodiment, an example in which the present technology is applied to a photodetection device that is a back-illuminated complementary metal oxide semiconductor (CMOS) image sensor is described.

### Overall Configuration of Photodetection Device

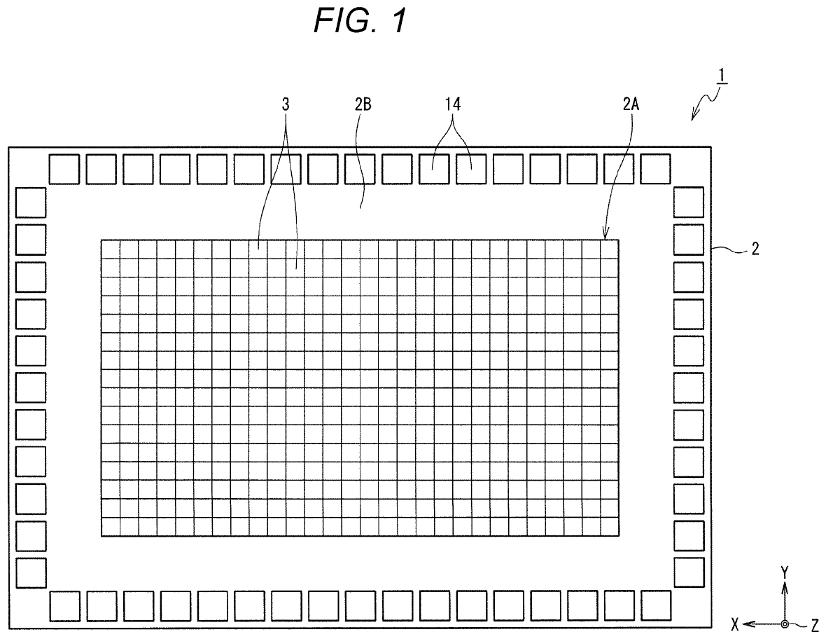

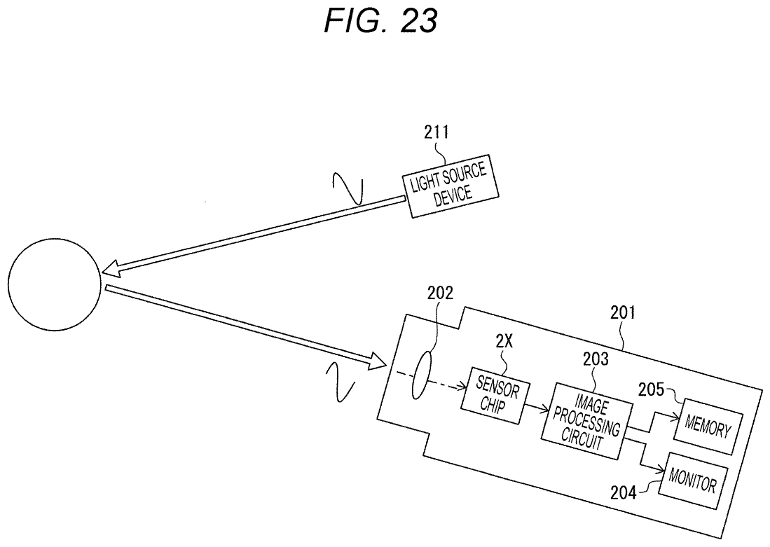

First, an overall configuration of a photodetection device 1 is described. As illustrated in FIG. 1, the photodetection device 1 according to the first embodiment of the present technology is formed mainly with a semiconductor chip 2 having a rectangular two-dimensional planar shape in planar view. That is, the photodetection device 1 is mounted on the semiconductor chip 2. As illustrated in FIG. 23, the photodetection device 1 captures image light from a subject via an optical system (optical lens) 202, converts the amount of incident light formed on an imaging surface into an electrical signal in units of pixels, and outputs the electrical signal as a pixel signal.

As illustrated in FIG. 1, the semiconductor chip 2 on which the photodetection device 1 is installed includes, in a two-dimensional plane including an X direction and a Y direction intersecting each other, a rectangular pixel region 2A provided in a central portion, and a peripheral region 2B provided outside the pixel region 2A to surround the pixel region 2A.

The pixel region 2A is a light receiving surface that receives light condensed by the optical system 202 illustrated in FIG. 23, for example. Then, in the pixel region 2A, a plurality of pixels 3 is arranged in an array on a two-dimensional plane including the X direction (for example, the row direction) and the Y direction (for example, the column direction). In other words, the pixels 3 are repeatedly disposed in each of the X direction and the Y direction intersecting each other in the two-dimensional plane. Note that, in the present embodiment, the X direction and the Y direction are orthogonal to each other, for example. Furthermore, a direction orthogonal to both the X direction and the Y direction is a Z direction (thickness direction, stacking direction). Furthermore, a direction perpendicular to the Z direction is a horizontal direction.

As illustrated in FIG. 1, a plurality of bonding pads 14 is arranged in the peripheral region 2B. Each bonding pad of the plurality of bonding pads 14 is arranged along each of the four sides of the two-dimensional plane of the semiconductor chip 2, for example. Each bonding pad of the plurality of bonding pads 14 is an input-output terminal that is used when the semiconductor chip 2 is electrically connected to an external device.

### Logic Circuit

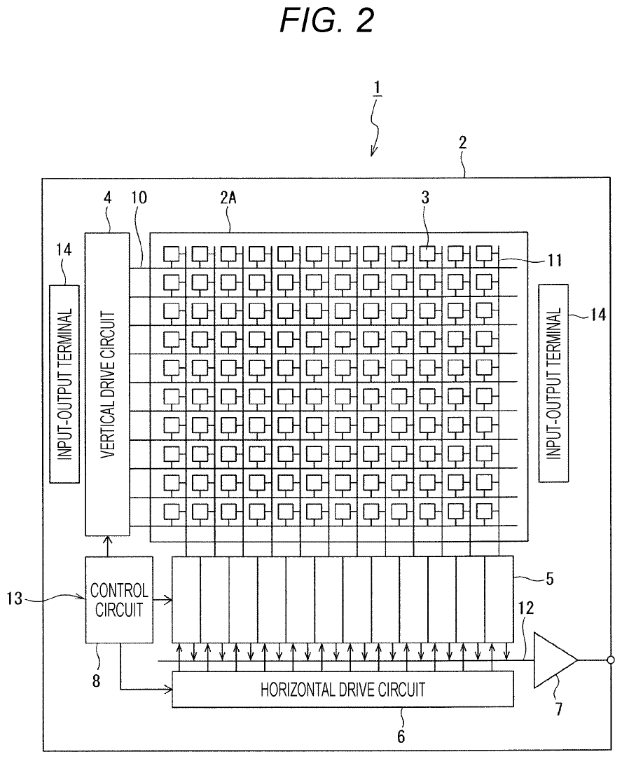

As illustrated in FIG. 2, the semiconductor chip 2 includes a logic circuit 13 including a vertical drive circuit 4, column signal processing circuits 5, a horizontal drive circuit 6, an output circuit 7, a control circuit 8, and the like. The logic circuit 13 includes a complementary MOS (CMOS) circuit including an n-channel conductive metal oxide semiconductor field effect transistor (MOSFET) and a p-channel conductive MOSFET as field effect transistors, for example.

The vertical drive circuit 4 includes a shift register, for example. The vertical drive circuit 4 sequentially selects a desired pixel drive line 10, supplies a pulse for driving the pixels 3 to the selected pixel drive line 10, and drives the respective pixels 3 row by row. That is, the vertical drive circuit 4 selectively scans each of the pixels 3 in the pixel region 2A sequentially in a vertical direction on a row-by-row basis, and supplies a pixel signal from each of the pixels 3 based on a signal charge generated in accordance with the amount of received light by a photoelectric conversion element of the pixel 3 to the column signal processing circuit 5 through a vertical signal line 11.

The column signal processing circuits 5 are disposed on the respective columns of the pixels 3, for example, and perform, for the respective pixel columns, signal processing such as noise removal on signals to be output from the pixels 3 of one row. For example, each column signal processing circuit 5 performs signal processing such as correlated double sampling (CDS) for removing pixel-specific fixed pattern noise, and analog-to-digital (AD) conversion. A horizontal selection switch (not illustrated) is disposed in the output stage of each column signal processing circuit 5, and is connected to a horizontal signal line 12.

The horizontal drive circuit 6 includes a shift register, for example. The horizontal drive circuit 6 sequentially outputs horizontal scanning pulses to the column signal processing circuits 5 to sequentially select each of the column signal processing circuits 5, and causes each of the column signal processing circuits 5 to output a pixel signal subjected to signal processing to the horizontal signal line 12.

The output circuit 7 performs signal processing on pixel signals sequentially supplied from the individual column signal processing circuits 5 through the horizontal signal line 12, and outputs a processed signal. As the signal processing, buffering, black level adjustment, column variation correction, various kinds of digital signal processing, and the like can be used, for example.

The control circuit 8 generates a clock signal and a control signal that are references for operations of the vertical drive circuit 4, the column signal processing circuits 5, the horizontal drive circuit 6, and the like, on the basis of a vertical synchronization signal, a horizontal synchronization signal, and a master clock signal. Then, the control circuit 8 outputs the generated clock signal and control signal to the vertical drive circuit 4, the column signal processing circuits 5, the horizontal drive circuit 6, and the like.

### Pixel

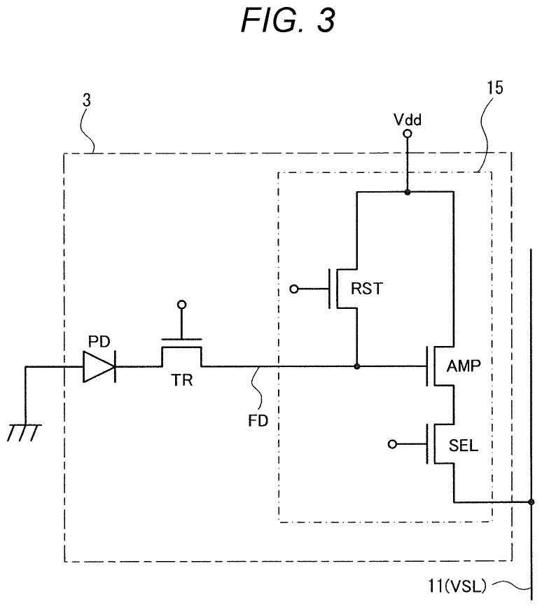

FIG. 3 is an equivalent circuit diagram illustrating a configuration example of the pixel 3. The pixel 3 includes a photoelectric conversion element PD, a charge accumulation region (floating diffusion) FD that accumulates (holds) a signal charge photoelectrically converted by the photoelectric conversion element PD, and a transfer transistor TR that transfers the signal charge photoelectrically converted by the photoelectric conversion element PD to the charge accumulation region FD. Furthermore, the pixel 3 includes a readout circuit 15 electrically connected to the charge accumulation region FD.

The photoelectric conversion element PD generates a signal charge corresponding to the amount of received light. Furthermore, the photoelectric conversion element PD temporarily accumulates (holds) the generated signal charge. The photoelectric conversion element PD has a cathode side electrically connected to a source region of the transfer transistor TR, and an anode side electrically connected to a reference potential line (for example, ground). As the photoelectric conversion element PD, for example, a photodiode is used.

The drain region of each transfer transistor TR is electrically connected to the charge accumulation region FD. A gate electrode of each transfer transistor TR is electrically connected to a transfer transistor drive line among the pixel drive lines 10 (see FIG. 2).

The charge accumulation region FD temporarily accumulates and holds the signal charge transferred from the photoelectric conversion element PD via the transfer transistor TR.

The readout circuit 15 reads the signal charge accumulated in the charge accumulation region FD, and outputs a pixel signal based on the signal charge. Although not limited to this, the readout circuit 15 includes an amplification transistor AMP, a selection transistor SEL, and a reset transistor RST as pixel transistors, for example. Each of these transistors (AMP, SEL, and RST) includes a MOSFET including a gate insulating film formed with a silicon oxide film (SiO₂ film), a gate electrode, and a pair of main electrode regions functioning as the source region and the drain region, for example. Furthermore, each of these transistors may be a metal insulator semiconductor FET (MISFET) whose gate insulating film is a silicon nitride film (Si₃N₄ film) or a film stack of a silicon nitride film and a silicon oxide film.

The amplification transistor AMP has a source region electrically connected to a drain region of the selection transistor SEL, and a drain region electrically connected to a power supply line Vdd and a drain region of the reset transistor. Then, a gate electrode of the amplification transistor AMP is electrically connected to the charge accumulation region FD and a source region of the reset transistor RST.

The selection transistor SEL has a source region electrically connected to the vertical signal line 11 (VSL), and a drain electrically connected to the source region of the amplification transistor AMP. Then, a gate electrode of the selection transistor SEL is electrically connected to a selection transistor drive line among pixel drive lines 10 (see FIG. 2).

The reset transistor RST has a source region electrically connected to the charge accumulation region FD and the gate electrode of the amplification transistor AMP, and a drain region electrically connected to the power supply line Vdd and the drain region of the amplification transistor AMP. A gate electrode of the reset transistor RST is electrically connected to a reset transistor drive line among the pixel drive lines 10 (see FIG. 2).

### Specific Configuration of Photodetection Device

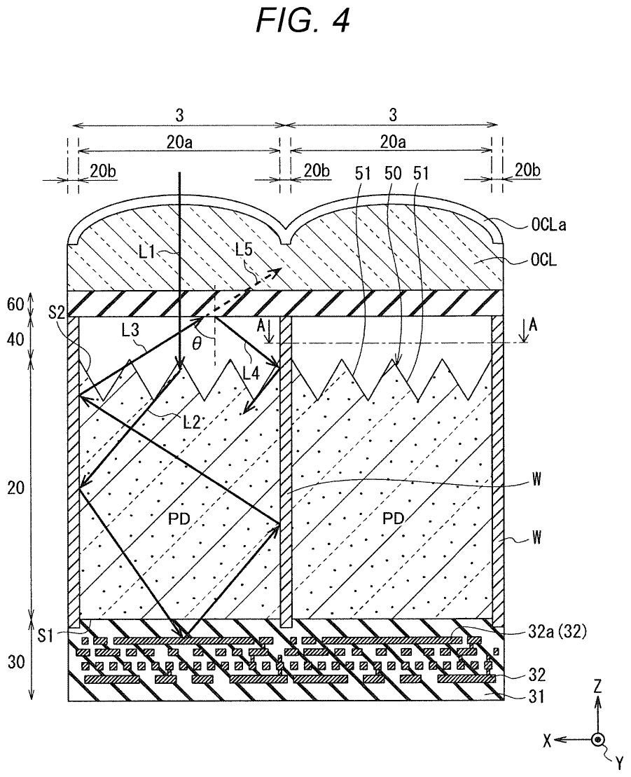

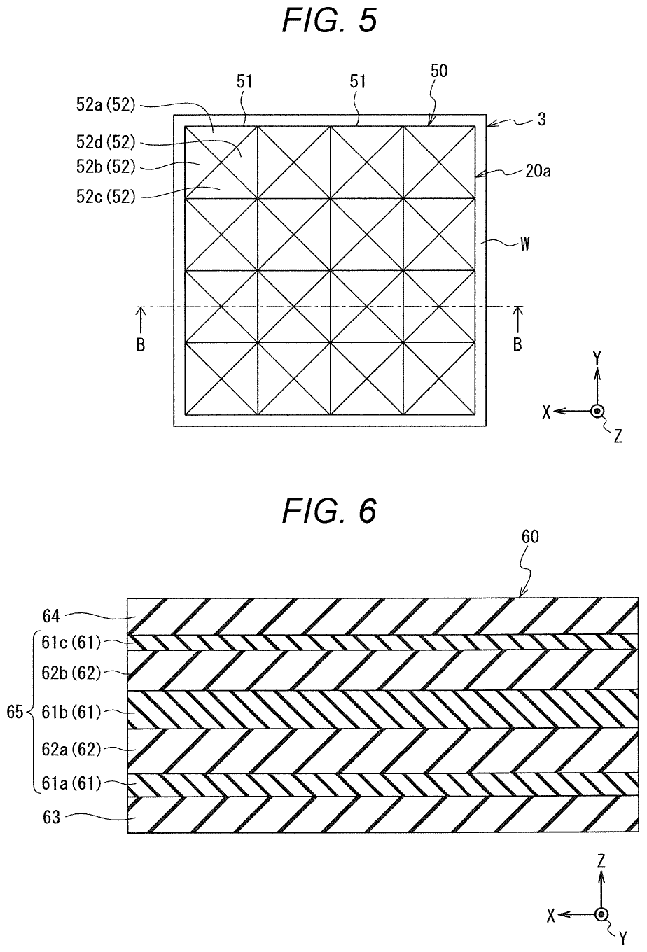

Next, a specific configuration of the photodetection device 1 will be described. FIG. 4 is a view illustrating a longitudinal cross-sectional structure of two pixels 3. FIG. 5 is a view illustrating a cross-sectional structure along the A-A cutting line for one pixel of the two pixels 3 illustrated in FIG. 4. Furthermore, FIG. 4 illustrates a cross-sectional structure taken along line B-B illustrated in FIG. 5. Note that the number of pixels 3 is not limited to that in FIG. 5.

### Stacked Structure of Photodetection Device

As illustrated in FIG. 4, the photodetection device 1 includes a semiconductor layer 20 having a first surface S1 and a second surface S2 located on sides opposite to each other. The semiconductor layer 20 includes, for example, a single crystal silicon substrate. Further, the photodetection device 1 includes a wiring layer 30 including an interlayer insulating film 31 and a wiring 32 stacked on the first surface S1 side of the semiconductor layer 20 in an overlapping manner. Furthermore, the photodetection device 1 includes members such as an insulating layer 40, a multilayer film filter 60, and a microlens (on-chip lens) OCL sequentially stacked on the second surface S2 side of the semiconductor layer 20. Note that a pinning layer covering the second surface S2 of the semiconductor layer 20 may be provided. In addition, the first surface S1 of the semiconductor layer 20 may be referred to as an element formation surface or a main surface, and the second surface S2 side may be referred to as a light incident surface or a back surface. Furthermore, the photodetection device 1 has an uneven shape 50 provided in a photoelectric conversion region 20a described later. Then, at least a part of incident light incident on the photodetection device 1 passes through the microlens OCL, the multilayer film filter 60, the insulating layer 40, and the semiconductor layer 20 in this order among the above-described components.

### Semiconductor Layer

The semiconductor layer 20 includes a semiconductor substrate. The semiconductor layer 20 includes, for example, a single crystal silicon substrate. Then, in the semiconductor layer 20, a photoelectric conversion region 20a is provided for each pixel 3. The light transmitted through the multilayer film filter 60 is incident on the photoelectric conversion region 20a. Note that, although described in detail later, in the present embodiment, an example in which the multilayer film filter 60 is a band pass filter that mainly transmits near-infrared light has been described. Then, mainly near-infrared light is incident on the photoelectric conversion region 20a. It is known that the absorption rate of near-infrared light in silicon is lower than that of visible light. Therefore, it is desirable that the near-infrared light incident on the photoelectric conversion region 20a is reflected in the photoelectric conversion region 20a, and the optical path length in the photoelectric conversion region 20a is made as long as possible to increase the absorption amount.

### Photoelectric Conversion Region

The semiconductor layer 20 has an island-shaped photoelectric conversion region (element formation region) 20a partitioned by an isolation region 20b. The photoelectric conversion regions 20a are provided for the respective pixels 3, and are arranged in an array along the X direction and the Y direction. The photoelectric conversion region 20a includes a semiconductor region of a first conductivity type (for example, p-type) and a semiconductor region of a second conductivity type (for example, n-type). Then, the photoelectric conversion element PD illustrated in FIG. 3 is formed in the photoelectric conversion region 20a. At least a part of the photoelectric conversion region 20a photoelectrically converts incident light to generate signal charges.

The isolation region 20b is not limited thereto, but is, for example, a trench structure in which an isolation groove is formed in the semiconductor layer 20 and a material that reflects light is embedded in the isolation groove. In the present embodiment, a material that reflects light is embedded in the separation groove to form a separation wall W to be described later.

### Uneven Shape

As illustrated in FIGS. 4 and 5, the side of the second surface S2 (side of the light incident surface) of the photoelectric conversion region 20a has an uneven shape 50. More specifically, the uneven shape 50 is formed by providing one or more recesses 51 in the photoelectric conversion region 20a from the second surface S2 side. In the present embodiment, as illustrated in FIG. 5, 16 recesses 51 are provided for each photoelectric conversion region 20a, but the number of recesses 51 is not limited to that of FIG. 5, and only required to be one or more. The recesses 51 each have a shape in which a regular quadrangular pyramid is turned upside down, and have four triangular inclined surfaces 52a, 52b, 52c, and 52d. Each of the inclined surfaces 52a, 52b, 52c, and 52d is a surface oblique to a thickness direction of the semiconductor layer 20. Note that, in a case where there is no need to distinguish the inclined surfaces 52a, 52b, 52c, and 52d, the inclined surfaces 52a, 52b, 52c, and 52d are not distinguished and are simply referred to as the inclined surface 52. The uneven shape 50 functions as a scatterer that scatters light. The light transmitted through the multilayer film filter 60 is scattered by the uneven shape 50 and travels in various directions. In addition, the uneven shape 50 is not limited thereto, but may satisfy a diffraction condition.

### Insulating Layer

As illustrated in FIG. 4, the insulating layer 40 is deposited on the second surface S2 of the semiconductor layer 20 by, for example, a CVD method or the like. The insulating layer 40 is not limited thereto, but is, for example, a silicon oxide film. The insulating layer 40 deposited on the uneven shape 50 fills and flattens the recesses 51 of the uneven shape 50.

### Separation Wall

The separation wall W extends along the thickness direction (Z direction) of the semiconductor layer 20 and partitions between the adjacent photoelectric conversion regions 20a. More specifically, in the separation wall W, a portion extending in the Z direction and the X direction partitions between the photoelectric conversion regions 20a adjacent in the Y direction, and a portion extending in the Z direction and the Y direction partitions between the photoelectric conversion regions 20a adjacent in the X direction. The separation wall W is not limited thereto, but may be, for example, a full trench isolation (FTI). In addition, an end of the separation wall W on the second surface S2 side desirably extends into the insulating layer 40 and is connected to the multilayer film filter 60. Even if there is a gap between the separation wall W and the multilayer film filter 60, the gap is slight. Thus, light can be efficiently confined in one pixel 3.

The separation wall W is constituted by a material that reflects light. The separation wall W is made by metal, for example. It is more preferable to use a metal having high reflectance as the metal constituting the separation wall W. Examples of the material constituting the separation wall W include aluminum (Al), silver (Ag), and copper (Cu).

In addition, the separation wall W may be constituted by a material other than metal, and may be constituted by a material whose refractive index is smaller than the refractive index of the semiconductor layer 20. In that case, light is reflected due to a difference in refractive index from the semiconductor layer 20. Examples of such a material include air and silicon oxide (SiO₂).

In the present embodiment, an example in which the separation wall W is constituted by aluminum (Al) will be described. Note that, in a case where the separation wall W is made by metal, an insulating film is formed between the semiconductor layer 20 and the separation wall W to cut off electrical conduction between the semiconductor layer 20 and the separation wall W. However, in FIG. 4 and the subsequent drawings, illustration of an insulating film provided between the separation wall W and the semiconductor layer 20 is omitted.

### Multilayer Film Filter

The multilayer film filter 60 is a band pass filter that transmits light in a partial wavelength band among the incident light. The multilayer film filter 60 is an on-chip filter provided (stacked) integrally with the semiconductor layer 20 on the second surface S2 side of the semiconductor layer 20. Furthermore, the multilayer film filter 60 is provided at a position overlapping the photoelectric conversion region 20a in plan view, and is provided so as to continuously cover at least the pixel region 2A (FIG. 1) without interruption.

As illustrated in FIG. 6, the multilayer film filter 60 is a reflection type band pass filter having a stacked structure 65 in which a high refractive index layer 61 and a low refractive index layer 62 having a refractive index lower than that of the high refractive index layer 61 are alternately stacked. The multilayer film filter 60 further includes insulating films 63 and 64 on both sides of the stacked structure 65 described above. For example, as illustrated in FIG. 6, the multilayer film filter 60 has a configuration in which the insulating film 63, a high refractive index layer 61a, a low refractive index layer 62a, a high refractive index layer 61b, a low refractive index layer 62b, a high refractive index layer 61c, and the insulating film 64 are stacked in this order from the side closer to the semiconductor layer 20. Note that the number of stacked layers of the high refractive index layer 61 and the low refractive index layer 62 included in the stacked structure 65 is seven in the example illustrated in FIG. 6, but the number of stacked layers is not limited thereto. The number of stacked layers of the stacked structure 65 is, for example, seven or more, and can be appropriately set according to a wavelength band of light to be transmitted through the multilayer film filter 60. Furthermore, in a case where the layers (for example, from the high refractive index layer 61a to the high refractive index layer 61c) of the high refractive index layer 61 are not distinguished from each other, they are simply referred to as the high refractive index layer 61. Similarly, in a case where the layers (for example, from the low refractive index layer 62a to the low refractive index layer 62b) of the low refractive index layer 62 are not distinguished from each other, they are simply referred to as the low refractive index layer 62. Furthermore, the refractive index of the insulating film 63 is smaller than the refractive index of the high refractive index layer 61a, and the refractive index of the insulating film 64 is smaller than the refractive index of the high refractive index layer 61c.

The material constituting the high refractive index layer 61 is not limited thereto, and examples thereof include amorphous silicon (a-Si), polysilicon (poly-Si), titanium oxide (TiO₂), aluminum oxide (Al₂O₃), and silicon nitride (Si₃N₄). The material constituting the low refractive index layer 62 is not limited thereto, and examples thereof include silicon oxide (SiO₂) and carbon-containing silicon oxide (SiOC). The insulating films 63 and 64 may be constituted by the same material as the low refractive index layer 62. In the present embodiment, an example in which the high refractive index layer 61 is constituted by amorphous silicon, and the low refractive index layer 62 and the insulating films 63 and 64 are constituted by silicon oxide will be described.

Furthermore, film thicknesses of each layer of the high refractive index layer 61 and each layer of the low refractive index layer 62 can be appropriately set according to the performance required for the multilayer film filter 60. For example, in the multilayer film filter 60 illustrated in FIG. 6, the film thickness of each layer is provided to the following film thickness.

### Layer/Film Thickness

High refractive index layer 61c/45 nm to 65 nm
Low refractive index layer 62b/130 nm to 150 nm
High refractive index layer 61b/130 nm to 150 nm
Low refractive index layer 62a/120 nm to 140 nm
High refractive index layer 61a/40 nm to 60 nm

The multilayer film filter 60 has a transmission spectrum unique to the stacked structure 65 as described above. More specifically, the multilayer film filter 60 has characteristics described below with respect to light incident on the multilayer film filter 60 along the thickness direction of the multilayer film filter 60 and the semiconductor layer 20. The multilayer film filter 60 transmits light in a first wavelength band including a peak wavelength described later among incident light at a higher transmittance than light in other wavelength bands. More specifically, the multilayer film filter 60 transmits light in a first wavelength band having a peak wavelength described later in a central portion among the incident light at a higher transmittance than light in other wavelength bands. That is, the multilayer film filter 60 mainly transmits most of light in the first wavelength band. In other words, the multilayer film filter 60 reflects light in a wavelength band other than the first wavelength band among the incident light at a higher reflectance than the light in the first wavelength band.

The first wavelength band may be, for example, a band of visible light or a band other than visible light. The first wavelength band may be, for example, a band corresponding to red, green, blue, or the like, or a band corresponding to infrared light or near-infrared light. In the present embodiment, the multilayer film filter 60 will be described as a band pass filter that mainly transmits near-infrared light.

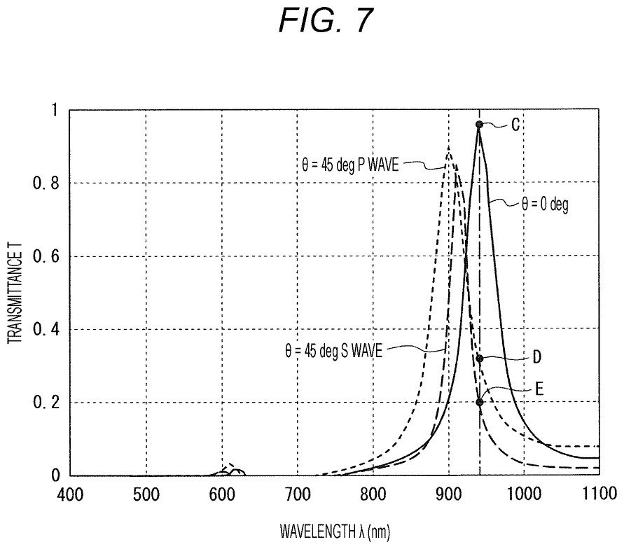

FIG. 7 is a graph illustrating a transmittance T of the multilayer film filter 60 with respect to a wavelength λ of light. FIG. 7 illustrates an example of a case where the transmittance T of the multilayer film filter 60 is designed to be maximum at a wavelength=940 nm. Then, the first wavelength band is a wavelength band centered on a wavelength of 940 nm. As illustrated, in a case where θ=0°, that is, light is perpendicularly incident on the multilayer film filter 60, the transmittance of light transmitted by the multilayer film filter 60 becomes maximum at a wavelength=940 nm. The maximum value of the transmittance is about 0.95 as indicated by a point C. The wavelength at which the transmittance is maximized is hereinafter referred to as a peak wavelength. Then, the transmittance T sharply drops at wavelengths before and after the peak wavelength. Thus, the light transmitted by the multilayer film filter 60 has a relatively sharp peak.

Note that the main light beam is not always perpendicularly incident on the multilayer film filter 60. Accordingly, a case where light is obliquely incident on the multilayer film filter 60 (θ≠0°) will be considered. When light is obliquely incident on the multilayer film filter 60, a phenomenon called a short wavelength shift occurs in which the peak of the transmittance T of light transmitted by the multilayer film filter 60 is shifted to the short wavelength side as compared with the case of θ=0°. FIG. 7 also illustrates the transmittance T of the multilayer film filter 60 with respect to the wavelength λ of light (P waves and S waves) incident on the multilayer film filter 60 at θ=45°. Although there is a slight difference in the shift amount between the P wave and the S wave, the transmittance profile with respect to the wavelength shifts to the short wavelength side in both waves. The peak wavelength of the P wave is about 900 nm, and is shifted to the short wavelength side by about 40 nm. Then, the peak wavelength of the S wave is about 910 nm, which is shifted to the short wavelength side by about 30 nm.

Then, the above-described short wavelength shift also occurs in a case where light that has passed through the multilayer film filter 60 and is incident on the semiconductor layer 20 is reflected and is obliquely re-incident on the multilayer film filter 60. In FIG. 4, when a main light beam L1 is incident on the multilayer film filter 60 at θ=0°, light having a peak at λ=940 nm among the incident light passes through the multilayer film filter 60. Then, after passing through the multilayer film filter 60, the main light beam L1 is scattered by the uneven shape 50, and its course becomes oblique (θ≠0°) like a light beam L2, for example. Thereafter, the light beam 12 changed in the traveling direction is reflected by the separation wall W and the wiring 32 to be described later in the pixel 3, and returns to the multilayer film filter 60 as an oblique (θ≠0°) light beam L3. In the light beam L3 traveling obliquely, a part of light beam L5 is transmitted through the multilayer film filter 60, and a part of light beam L4 is reflected by the multilayer film filter 60 by the short wavelength shift and returns into the semiconductor layer 20. Note that, since the light beam L3 has already been transmitted through the multilayer film filter 60 once, the light beam L3 is light in the first wavelength band having a peak at λ=940 nm. Then, when the light is re-incident on the multilayer film filter 60, a short wavelength shift occurs in the transmission characteristic of the multilayer film filter 60. For example, as illustrated in FIG. 7, when light is re-incident on the multilayer film filter 60 at θ=45°, a short wavelength shift occurs, and the peak wavelength of light transmitted by the multilayer film filter 60 is shifted to the short wavelength side. Therefore, the transmittance T of the multilayer film filter 60 at λ=940 nm changes from the value indicated by the point C to the values indicated by points D and E. More specifically, in the P waves, the transmittance T of the multilayer film filter 60 decreases from a transmittance of about 0.95 indicated by the point C to a transmittance of about 0.3 indicated by the point D. Furthermore, in the S waves, the transmittance T of the multilayer film filter 60 decreases from the transmittance of about 0.95 indicated by the point C to a transmittance of about 0.2 indicated by the point E.

Furthermore, the reflectance R of the multilayer film filter 60 can be obtained by subtracting the transmittance T from 1 (R=1−T). In the case of the P waves, the reflectance R of the multilayer film filter 60 at λ=940 nm is about 0.7. Furthermore, in the case of the S waves, the reflectance R of the multilayer film filter 60 at λ=940 nm is about 0.8. That is, at θ=45°, the reflectance R of the multilayer film filter 60 is greatly increased from the reflectance of about 0.05 in the case of θ=0°.

As described above, in the light of λ=940 nm obliquely incident, the transmittance T of the multilayer film filter 60 decreases and the reflectance R increases as compared with the case of θ=0°. Therefore, in the light of λ=940 nm obliquely re-incident on the multilayer film filter 60, the amount of light transmitted through the multilayer film filter 60 decreases, and the amount of light reflected by the multilayer film filter 60 increases.

Note that the half-value width of the first wavelength band is preferably small. The smaller the half-value width of the first wavelength band, the sharper the peak of the transmittance T with respect to the wavelength λ, the higher the effect of reducing the transmittance of obliquely incident light, and the higher the effect of increasing the reflectance. The half-value width of the first wavelength band is, for example, 100 nm or less. The half-value width of the first wavelength band is preferably 50 nm or less. The half-value width of the first wavelength band is preferably 40 nm or less. The half-value width of the first wavelength band is preferably 30 nm or less. In addition, the multilayer film filter 60 may be designed so that the half-value width of the first wavelength band is the same as the shift amount of the short wavelength shift generated in the oblique light. Then, the half-value width of the first wavelength band may be 10 nm or more.

### Microlens

As illustrated in FIG. 4, the microlens OCL is, for example, an on-chip lens provided for each pixel 3 and having a function of collecting light to the photoelectric conversion region 20a. The microlens OCL may be constituted by, for example, an inorganic material such as silicon nitride or silicon oxynitride (SiON), or may be constituted by a material in which a high refractive index material is contained in various organic films. In addition, the microlens OCL may have an antireflection film OCLa for preventing reflection on the side opposite to the semiconductor layer 20.

### Wiring Layer

The wiring layer 30 is a multilayer wiring layer including an interlayer insulating film 31 and a plurality of layers of wiring 32. The wiring 32 transmits an image signal generated by the pixel 3. Furthermore, the wiring layer 30 includes a metal reflection layer 32a extending in the row direction and the column direction. As illustrated in FIG. 4, the reflection layer 32a has a function of reflecting light incident on the wiring layer 30 from the semiconductor layer 20. More specifically, the reflection layer 32a has a function of reflecting light incident on the wiring layer 30 from the semiconductor layer 20 toward the semiconductor layer 20. Furthermore, the wiring 32 also has a function of reflecting light. Moreover, the interlayer insulating film 31 can also reflect light due to a difference in refractive index from the semiconductor layer 20.

The wiring 32 and the reflection layer 32a are constituted by metal. Examples of the metal constituting the wiring 32 and the reflection layer 32a include aluminum (Al) and copper (Cu). The interlayer insulating film 31 is not limited thereto, and for example, a silicon oxide film or the like can be used. The interlayer insulating film 31 is not limited thereto, and is constituted by, for example, an insulating film such as silicon oxide.

### Manufacturing Method for Photodetection Device

Hereinafter, an example of a method for manufacturing the photodetection device 1 will be described. First, a semiconductor substrate on which the photoelectric conversion element PD, various transistors, and the like are formed is prepared, and the wiring layer 30 is stacked on the first surface S1 of the semiconductor substrate. Then, the surface of the semiconductor substrate opposite to the wiring layer 30 is ground to leave a portion to be the semiconductor layer 20. Then, the exposed surface of the semiconductor layer 20 becomes the second surface S2. Next, a resist pattern is formed on the second surface S2. More specifically, a resist pattern is formed so that a portion of the uneven shape 50 to be convex is protected by a resist. Then, a portion of the semiconductor layer 20 exposed from the opening of the resist pattern is etched by anisotropic etching to form the uneven shape 50 in the semiconductor layer 20. Thereafter, the insulating layer 40 is deposited on the second surface S2 of the semiconductor layer 20 to form the separation wall W.

Next, the multilayer film filter 60 is stacked on the exposed surface of the insulating layer 40. More specifically, the layers of the multilayer film filter 60 are sequentially stacked. Thereafter, microlenses OCL and the like are formed on the exposed surface of the multilayer film filter 60. In this manner, the photodetection device 1 is almost completed. The photodetection device 1 is formed in each of a plurality of chip formation regions defined by scribe lines (dicing lines) on a semiconductor wafer. The plurality of chip formation regions is then divided into single chips along the scribe lines, thereby forming the semiconductor chip 2 on which the photodetection device 1 is mounted is formed.

### Main Effects of First Embodiment

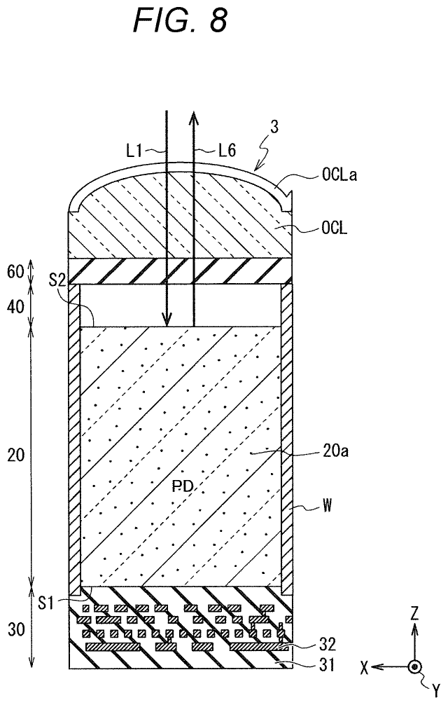

Hereinafter, a main effect of the first embodiment will be described, and before that, a photodetection device having no uneven shape illustrated in FIG. 8 will be described. In the photodetection device illustrated in FIG. 8, the photoelectric conversion region 20a does not have the uneven shape 50, and the second surface S2 is flat. Therefore, a part of the main light beam L1 transmitted through the multilayer film filter 60 along the thickness direction is reflected by the flat second surface S2, travels in parallel with the main light beam L1 as a light beam L6, and is re-incident on the multilayer film filter 60. Since the light beam L6 is incident on the multilayer film filter 60 along the thickness direction thereof, a short wavelength shift hardly occurs, and a large amount of the light beam L6 is transmitted through the multilayer film filter 60 and escapes to the outside of the multilayer film filter 60. Then, there is a possibility that the light that has escaped to the outside of the multilayer film filter 60 is re-reflected by the microlens OCL, a transparent substrate of a package (not illustrated) that seals the photodetection device, or the like, and is re-incident on the adjacent pixel. Then, there is a possibility that the light beam L6 re-incident on the adjacent pixel appears as a flare in the acquired image. Furthermore, in a case where the incident light is near-infrared light, since the absorption rate in silicon is lower than that of visible light, there is a possibility that the influence on the quantum efficiency (QE) due to the escape of light to the outside of the multilayer film filter 60 becomes larger than that in the case of visible light.

On the other hand, a photodetection device 1 according to a first embodiment of the present technology includes: a semiconductor layer 20 in which one surface is a light incident surface and another surface is an element formation surface, the semiconductor layer including a plurality of photoelectric conversion regions 20a arranged in an array along a row direction and a column direction perpendicular to a thickness direction; and a multilayer film filter 60 provided integrally with the semiconductor layer 20 on a side of the light incident surface of the semiconductor layer 20 and provided at a position overlapping the photoelectric conversion regions 20a, in which a side of the light incident surface of the photoelectric conversion region 20a has an uneven shape 50, and the multilayer film filter 60 transmits light in a first wavelength band at a higher transmittance than light in other wavelength bands among light incident along the thickness direction. As described above, since the side of the light incident surface of the photoelectric conversion region 20a has the uneven shape 50, the light transmitted through the multilayer film filter 60 along the thickness direction is scattered by the uneven shape 50. Therefore, the light is suppressed from being re-incident on the multilayer film filter 60 along the thickness direction of the multilayer film filter 60. Thus, the amount of light that re-transmits through the multilayer film filter 60 and escapes to the outside of the multilayer film filter 60 can be suppressed, so that flare can be suppressed. Furthermore, this makes it possible to suppress reduction in the amount of light reflected by the multilayer film filter 60 toward the photoelectric conversion region 20a, and to suppress reduction in the amount of light returning to the photoelectric conversion region 20a. Thus, it is possible to suppress a decrease in the optical path length of the incident light in the photoelectric conversion region 20a, and it is possible to suppress a decrease in quantum efficiency (QE). Therefore, it is possible to suppress a decrease in sensitivity of the photodetection device 1. More specifically, the amount of light reflected by the multilayer film filter 60 toward the photoelectric conversion region 20a side can be increased, and the amount of light returning to the photoelectric conversion region 20a can be increased. Thus, the optical path length of the incident light in the photoelectric conversion region 20a can be increased, and the quantum efficiency (QE) can be increased. Therefore, the sensitivity of the photodetection device 1 can be increased. Furthermore, even in a case where the incident light is near-infrared light, a decrease in quantum efficiency (QE) can be suppressed, and the quantum efficiency (QE) can be increased.

Furthermore, the photodetection device 1 according to the first embodiment of the present technology includes the separation wall W extending along the thickness direction and partitioning between the photoelectric conversion regions 20a adjacent in the row direction and the column direction, and the end of the separation wall W on the side of the light incident surface is connected to the multilayer film filter 60. Even if there is a gap between the separation wall W and the multilayer film filter 60, the gap is small, so that it is possible to suppress the amount of light leaking from between the separation wall W and the multilayer film filter 60 to the adjacent pixel, to suppress flare, and to suppress a decrease in quantum efficiency (QE). Therefore, it is possible to suppress a decrease in sensitivity of the photodetection device 1.

Note that, in the photodetection device 1 according to the first embodiment, the multilayer film filter 60 includes the insulating film 63, but need not include the insulating film 63. In a case where the insulating film 63 is not included, the high refractive index layer 61a of the multilayer film filter 60 may be directly stacked on the insulating layer 40.

Furthermore, the photodetection device 1 according to the first embodiment includes the microlens OCL, but need not include the microlens OCL.

In addition, a support substrate may be overlapped and joined to a surface of the wiring layer 30 opposite to the semiconductor layer 20.

### Modifications of First Embodiment

In the description below, modifications of the first embodiment are explained.

### Modification 1

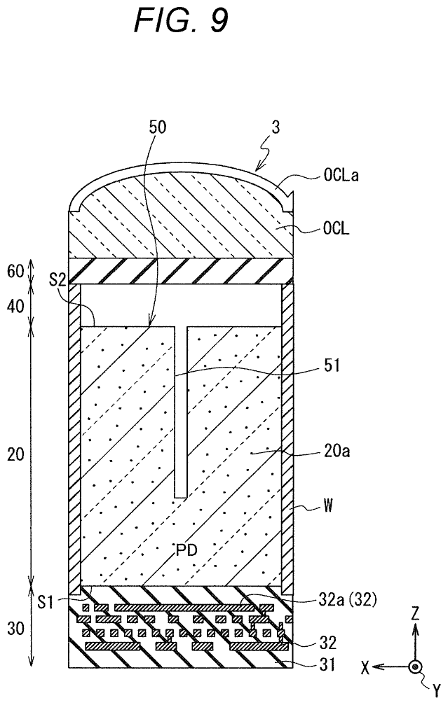

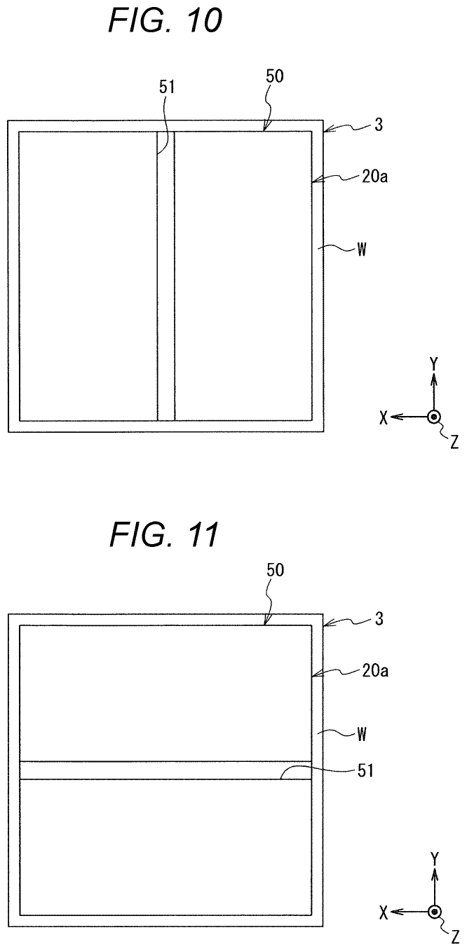

The recesses 51 of the photodetection device 1 according to the first embodiment each have a shape in which a regular quadrangular pyramid is turned upside down, but the present technology is not limited thereto. As illustrated in FIGS. 9 and 10, a recess 51 of the photodetection device 1 according to Modification 1 of the first embodiment may be a groove recessed in the thickness direction of the semiconductor layer 20.

The recess 51 is a trench-shaped groove extending along the Y direction and the Z direction. A material having a refractive index smaller than the refractive index of the semiconductor layer 20 is embedded in the groove. Then, due to the difference in refractive index between such a material and the semiconductor layer 20, it functions as a scatterer that reflects light and scatters light. Examples of the material having a refractive index smaller than the refractive index of the semiconductor layer 20 include air and silicon oxide (SiO₂).

Effects similar to those of the photodetection device 1 according to the first embodiment described above can also be achieved with the photodetection device 1 according to Modification 1 of the first embodiment.

### Modification 2

The recess 51 of the photodetection device 1 according to Modification 1 of the first embodiment is a trench-shaped groove extending along the Y direction and the Z direction, but the present technology is not limited thereto. As illustrated in FIG. 11, a recess 51 of the photodetection device 1 according to Modification 2 of the first embodiment may be a trench-shaped groove extending along the X direction and the Z direction.

Effects similar to those of the photodetection device 1 according to the first embodiment described above can also be achieved with the photodetection device 1 according to Modification 2 of the first embodiment.

### Modification 3

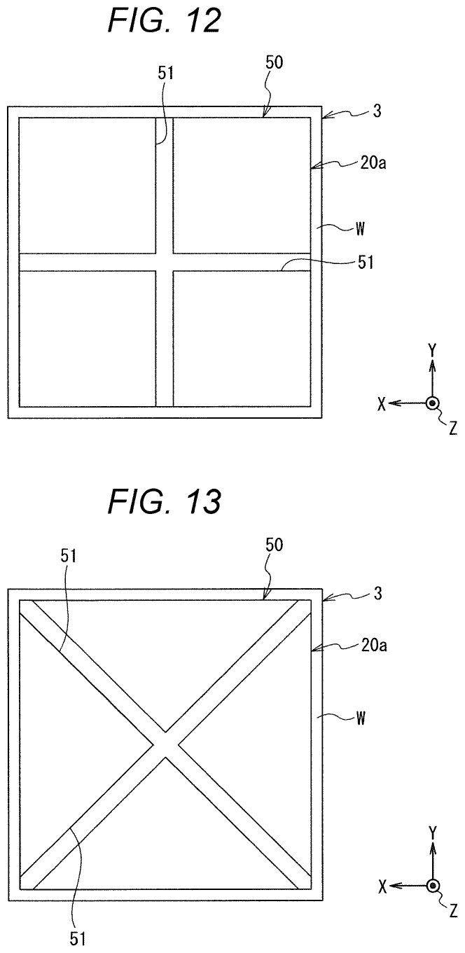

The photodetection device 1 according to Modification 1 and Modification 2 of the first embodiment has one recess 51 for each photoelectric conversion region 20a, but the present technology is not limited thereto. As illustrated in FIG. 12, the photodetection device 1 according to Modification 3 of the first embodiment may have a plurality of recesses 51 for each photoelectric conversion region 20a.

FIG. 12 illustrates an example in which the photodetection device 1 has two recesses 51 for each photoelectric conversion region 20a. The photodetection device 1 includes a recess 51 that is a groove extending along the Y direction and the Z direction and a recess 51 that is a groove extending along the X direction and the Z direction for each photoelectric conversion region 20a.

Effects similar to those of the photodetection device 1 according to the first embodiment described above can also be achieved with the photodetection device 1 according to Modification 3 of the first embodiment.

### Modification 4

In the photodetection device 1 according to Modification 4 of the first embodiment, as illustrated in FIG. 13, two recesses 51 extend along diagonal line directions and the Z direction of the photoelectric conversion region 20a. The two recesses 51 extend along diagonal directions different from each other.

Effects similar to those of the photodetection device 1 according to the first embodiment described above can also be achieved with the photodetection device 1 according to Modification 4 of the first embodiment.

### Second Embodiment

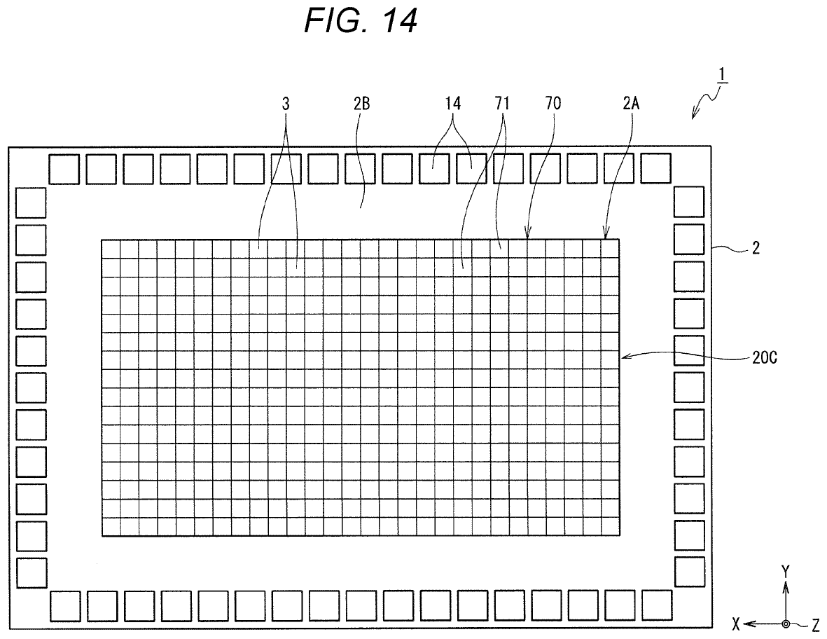

A second embodiment of the present technology illustrated in FIGS. 14 to 16 and FIGS. 17A to 17C will be described below. The photodetection device 1 according to the second embodiment is different from the photodetection device 1 according to the first embodiment described above in that an optical element 71 is provided on the side of the multilayer film filter 60 opposite to the semiconductor layer 20 side, and other configurations of the photodetection device 1 are basically similar to those of the photodetection device 1 according to the first embodiment described above. Note that the components already described are denoted by the same reference numerals, and the description thereof will be omitted. Note that, in FIGS. 14 to 16 and FIGS. 17A to 17C, there is a case where there is a difference in configuration between the drawings, but the present technology can be implemented in either configuration.

A main light beam is incident substantially perpendicularly on the pixel 3 near the center of the pixel region 2A illustrated in FIG. 14. On the other hand, the main light beam is obliquely incident on the pixel 3 from near the center of the pixel region 2A toward the edge, that is, as the image height increases. When the main light beam is obliquely incident on the pixel 3, a short wavelength shift occurs, and the wavelength of the main light beam transmitted through the multilayer film filter 60 becomes short. Moreover, in a case where the incident light diagonally transmitted through the multilayer film filter 60 is reflected in the photoelectric conversion region 20a and is re-incident on the multilayer film filter 60 as oblique reflected light, there is a possibility that the difference in the incident angle with respect to the multilayer film filter 60 between the incident light and the reflected light becomes insufficient, and the light transmitted through the multilayer film filter 60 out of the reflected light becomes larger than the reflected light. For example, in a case where the incident light is incident on the multilayer film filter 60 at 30° and the reflected light is incident on the multilayer film filter 60 at 30°, it is conceivable that the amount of light transmitted through the multilayer film filter 60 out of the reflected light is larger than the amount of light reflected. Accordingly, in the present embodiment, by providing the optical element 71, even in a pixel arranged at a position with a high image height, the main light beam is suppressed from being incident on the multilayer film filter 60 at an angle far from perpendicular.

### Specific Configuration of Photodetection Device

In the description below, the configuration of the photodetection device 1 according to the second embodiment of the present technology will be described with a focus on portions different from the configuration of the photodetection device 1 according to the first embodiment described above.

### Stacked Structure of Photodetection Device

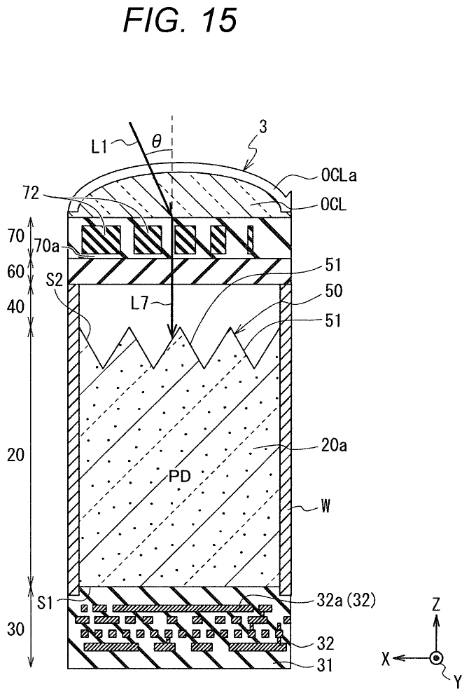

As illustrated in FIG. 15, the photodetection device 1 (semiconductor chip 2) includes an optical element layer 70 provided between the multilayer film filter 60 and the microlens OCL. The optical element layer 70 is an on-chip element provided integrally with (stacked on) the semiconductor layer 20 on the second surface S2 side of the semiconductor layer 20 together with the multilayer film filter 60.

### Optical Element Layer

As illustrated in FIG. 14, the optical element layer 70 is provided at a position overlapping at least a pixel region 2A (light receiving region 20C) in plan view. The optical element layer 70 is provided at a position exactly overlapping the pixel region 2A (light receiving region 20C) in plan view. The optical element layer 70 is formed by arranging a plurality of optical elements 71 in a two-dimensional array. The optical elements 71 are provided for respective pixels 3, that is, for respective photoelectric conversion regions 20a. One optical element 71 is provided at a position overlapping one photoelectric conversion region 20a in plan view. Note that the light receiving region 20C is a region formed by arranging a plurality of photoelectric conversion regions 20a in the semiconductor layer 20 in a two-dimensional array. Then, the light transmitted through the optical element layer 70 is incident on the multilayer film filter 60.

### Optical Element

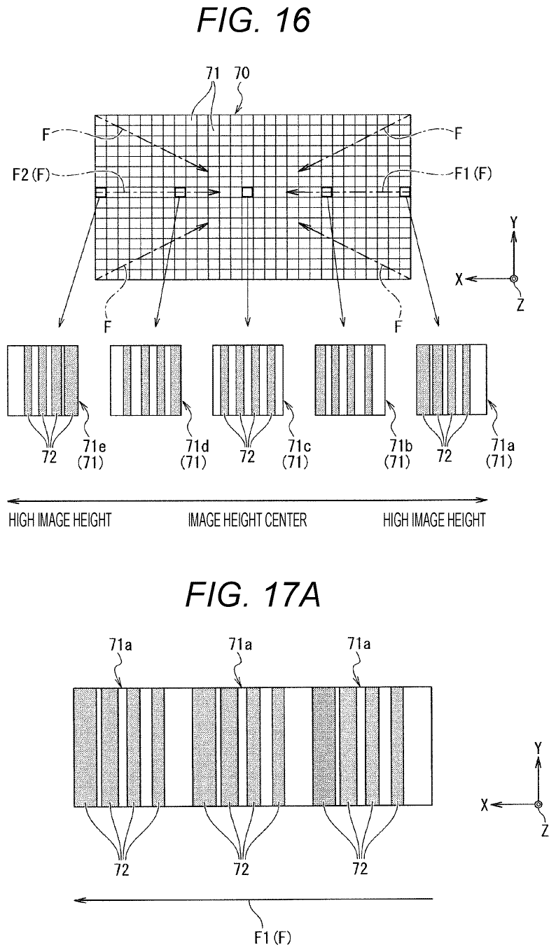

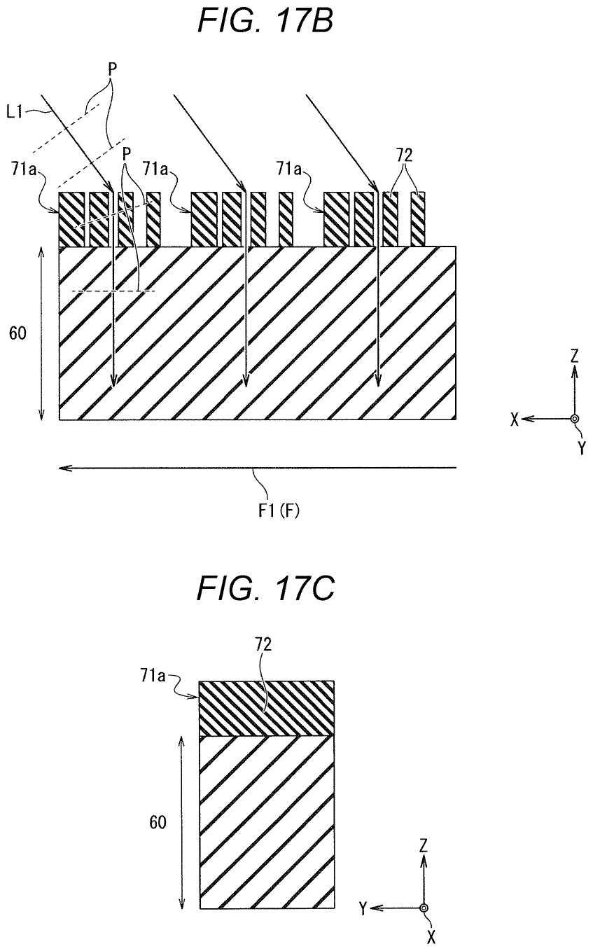

FIGS. 17A, 17B, and 17C illustrate optical elements 71a illustrated in FIG. 16 as an example of the optical elements 71. FIGS. 17A, 17B, and 17C illustrate an example in which three optical elements 71a are arranged along the X direction. As illustrated in FIG. 17B, the optical elements 71 are meta-surface optical elements provided to deflect the traveling direction of the main light beam so as to approach the Z direction. Therefore, the optical elements 71 are provided upstream of the multilayer film filter 60 in the light traveling direction. Here, the meta-surface optical elements are optical elements that each include a plurality of artificial structures 72 having a width sufficiently smaller than the wavelength of light and exhibits physical properties and functions that are not present in nature. As illustrated in FIGS. 15 and 17B, a main light beam L1 obliquely incident on the optical elements 71a is deflected by the optical elements 71a so that the traveling direction of the main light beam L1 approaches the Z direction (main light beam L7 in FIG. 15). Since the traveling direction of the main light beam L1 is deflected by the optical elements 71, it is possible to suppress incidence of the main light beam L1 on the multilayer film filter 60 at an angle far from the perpendicular.

One optical element 71 has a plurality of structures 72 arranged at intervals in a width direction in plan view. In the present embodiment, the structures 72 each have a plate shape and extend linearly in the longitudinal direction in plan view. Note that the number of structures 72 included in one optical element 71 is not limited to the illustrated number. Furthermore, the width direction is a width direction of the structures 72. More specifically, it is a lateral direction out of a longitudinal direction and a lateral direction in a plan view of the structures 72. Then, in plan view, the pitch in the width direction of the structures 72 is equal to or less than the wavelength of the target light. Furthermore, the pitch in the width direction of the structures 72 may be equal to or less than ½ of the wavelength of the target light. For example, the pitch in the width direction of the structures 72 is desirably a pitch of less than 400 nm at a short wavelength end with respect to 400 to 650 nm as a visible range. In addition, the pitch in the width direction of the structures 72 is desirably, for example, a pitch of less than 800 nm at a short wavelength end for light of near-infrared rays of 800 to 1000 nm. With such a configuration, stray light due to diffraction can be suppressed. As illustrated in FIGS. 17B and 17C, the height direction of the structures 72 is a direction along the Z direction. Dimensions of the structures 72 in the height direction are on the order of submicrons, and are substantially the same in the plurality of structures 72.

The structures 72 are constituted by a material that transmits light. The structures 72 are preferably constituted by a material having a high refractive index. Examples of a material constituting the structures 72 include silicon nitride (Si₃N₄), titanium oxide (TiO₂), tantalum oxide (Ta₂O₅), and aluminum oxide (Al₂O₃). In the present embodiment, it is assumed that the structures 72 are constituted by silicon nitride. Furthermore, a portion of the optical element 71 not provided with the structures 72 may be occupied by air as illustrated in FIG. 17B, and a material (for example, silicon oxide) having a refractive index lower than that of the material constituting the structures 72 may be provided as illustrated in FIG. 15.

Then, as illustrated in FIG. 17A, the density occupied by the structures 72 in one optical element 71a in plan view is higher on the left side of the optical element 71a in the drawing (the portion close to the center of the light receiving region 20C) than on the right side of the drawing (the portion close to the edge of the light receiving region 20C). That is, the distribution of the left side of the paper surface and the right side of the paper surface of the optical element 71a is asymmetric with respect to the center in the left-right direction of the paper surface. Note that this is a feature in a case where the optical element 71a is used as an example, and in any (or all) of optical elements 71 arranged to overlap at a position away from the center of the light receiving region 20C in plan view as illustrated in FIG. 16, the structures 72 have an asymmetric distribution with respect to the center of a portion on an edge side and a portion on a center side of the light receiving region 20C in the optical element 71 in plan view. More specifically, the density occupied by the structures 72 having a refractive index higher than that of air in one optical element 71a in plan view gradually increases from the right side to the left side in the drawing of FIG. 17A (along direction F1). Therefore, the refractive index of one optical element 71a gradually increases from the right side to the left side in the drawing. The density occupied by the structures 72 in the one optical element 71a in plan view can be gradually increased along the direction F1 by performing at least one of gradually increasing the dimensions in the width direction of the structures 72 from the right side to the left side in the drawing (along the direction F1) and gradually decreasing the pitch at which the structures 72 are arranged from the right side to the left side in the drawing (along the direction F1) in the one optical element 71a. Furthermore, for example, the pitch at which the structures 72 are arranged may be constant, and the dimension of the structure 72 in the width direction may be gradually increased from the right side to the left side in the drawing (along the direction F1). The dimensions of the structures 72 in the width direction may be constant, and the pitch at which the structures 72 are arranged may be gradually reduced from the right side to the left side in the drawing (along the direction F1).

Such an optical element 71a can change the phase of the main light beam as illustrated in FIG. 17B. More specifically, in the optical element 71a, the phase of the main light beam can be made slower in a portion where the structures 72 are densely provided. The optical element 71a is an optical element disposed so as to overlap a position (a position having a high image height) away from the center of the light receiving region 20C in plan view. Therefore, the main light beam L1 is obliquely incident on the optical element 71a. Furthermore, the direction F1 is a direction from the edge of the light receiving region 20C toward the center. When the main light beam L1 is incident on the optical element 71a, a wavefront P of light extending in the direction perpendicular to the traveling direction of the light is also obliquely incident on the optical element 71a. The wavefront P of light is first incident on a portion of the optical element 71a where the structures 72 are densely provided. Then, in such a portion, the phase of the wavefront P is delayed. Then, the wavefront P is also sequentially incident on a portion of the optical element 71a where the density occupied by the structures 72 is low. Then, in such a portion, the phase delay of the wavefront P is gentle, if any, as compared with a portion where the density occupied by the structures 72 is high. Thus, a portion traveling with a delay is formed on the wavefront P obliquely incident on the optical element 71a, the wavefront P is rotated along the direction perpendicular to the paper surface, and the traveling direction of the main light beam L1 is deflected. As described above, by providing the plurality of structures 72 so as to be gradually denser along the direction (direction F1) from the portion close to the edge of the light receiving region 20C toward the portion close to the center of the optical element 71a, the traveling direction of the main light beam L1 can be deflected to approach the Z direction.

FIG. 16 illustrates some of the plurality of optical elements 71 included in the optical element layer 70 in an enlarged manner. More specifically, FIG. 16 illustrates the optical elements 71a, 71b, 71c, 71d, and 71e in an enlarged manner. Note that, in a case where the optical elements 71a, 71b, 71c, 71d, and 71e are not distinguished, they are simply referred to as the optical elements 71. Furthermore, FIG. 16 illustrates a plurality of directions F from the edge toward the center of the light receiving region 20C. As illustrated, the direction F radially extends from the edge of the light receiving region 20C to the center. The optical element 71a to the optical element 71e are arranged in this order at intervals along the X direction. Among them, the optical element 71c is disposed so as to overlap the vicinity of the center of the light receiving region 20C. Then, the optical elements 71a and 71b are arranged along the direction F1, and the optical elements 71d and 71e are arranged along the direction F2. Note that, in a case where the directions F1 and F2 are not distinguished, they are simply referred to as a direction F. Each of the optical elements 71a, 71b, 71d, and 71e is one optical element (first optical element) disposed so as to overlap a position (position having a high image height) away from the center of the light receiving region 20C in plan view. Among the optical elements 71a, 71b, 71d, and 71e, the optical elements 71a and 71e are located closest to the edge of the light receiving region 20C. Each of the optical elements 71b and 71d arranged to overlap a position closer to the center of the light receiving region 20C than the optical elements 71a and 71e (first optical element) in plan view is also another optical element (second optical element). That is, the second optical element is an optical element positioned between the first optical element and the optical element 71 (third optical element) arranged so as to overlap the vicinity of the center (image height center) of the light receiving region 20C.

As illustrated in FIG. 16, in the optical elements 71a, 71b, 71c, 71d, and 71e, the arrangement direction of the structures 72 is a direction along the direction F (in the present embodiment, the directions F1 and F2), but the widths, the arrangement pitches, the arrangement positions, and the like of the structures 72 are different. As described above, the widths and the arrangement positions of the structures 72 included in the optical element 71 are different depending on the arrangement positions of the optical elements 71 in the optical element layer 70. The widths, arrangement positions, and the like of the structures 72 are only required to be designed according to the arrangement positions of the optical elements 71 in the optical element layer 70 and the incident angle of the main light beam.

As illustrated in FIG. 16, in one optical element 71, for example, the optical element 71a, arranged to overlap a position away from the center of the light receiving region 20C in plan view, the structures 72 are arranged along a direction from a portion of the optical element 71a close to the edge of the light receiving region 20C toward a portion close to the center. The structures 72 of the optical element 71a are arranged along the direction F1. Then, the density occupied by the structures 72 in the optical element 71a in plan view is higher in a portion of the optical element 71a close to the center of the light receiving region 20C than in a portion close to the edge. More specifically, the density occupied by the structures 72 in the optical element 71a in plan view gradually increases from a portion close to the edge of the light receiving region 20C to a portion close to the center of the optical element 71a (along the direction F1).

Such a feature is the same for the optical element 71 (second optical element, for example, optical element 71b and optical element 71d) arranged so as to overlap a position closer to the center of the light receiving region 20C than the optical element 71a (first optical element) in plan view. However, when comparing the optical element 71a and the optical element 71b, in plan view, the density occupied by the structures 72 in the portion of the optical element 71a close to the edge (center) of the light receiving region 20C is higher than the density occupied by the structures 72 in the portion of the optical element 71b close to the center of the light receiving region 20C. That is, the optical element 71 disposed so as to overlap a position closer to the edge of the light receiving region 20C in plan view has a higher density occupied by the structures 72 in a portion closer to the center of the light receiving region 20C. Then, the optical element 71 disposed so as to overlap a position closer to the center of the light receiving region 20C in plan view has a lower density occupied by the structures 72 in a portion closer to the center of the light receiving region 20C. This is because the incident angle θ of the main light beam varies depending on the position of the optical element 71 in the optical element layer 70, and the required deflection angle also varies depending on the position of the optical element 71 in the optical element layer 70.

For example, the angle θ between the incident main light beam and the Z direction becomes larger as the optical element 71 is arranged so as to overlap a position closer to the edge of the light receiving region 20C in plan view. This is because, in order to deflect such a main light beam so as to approach the z direction, it is necessary to increase the density occupied by the structures 72 in a portion close to the center of the light receiving region 20C of the optical element 71 and to increase the deflection angle. Furthermore, for example, the angle θ between the incident main light beam and the Z direction becomes smaller as the optical element 71 is arranged to overlap a position closer to the center of the light receiving region 20C in plan view. In this case, the angle for deflecting the main light beam to approach the Z direction may be small, and thus the gradient of the density of the structures 72 only needs to be lowered in a portion close to the center of the light receiving region 20C of the optical element 71. As described above, the optical element 71 disposed so as to overlap the edge of the light receiving region 20C in plan view has a higher density occupied by the structures 72 in a portion closer to the center of the light receiving region 20C.

The same applies to the optical element 71e and the optical element 71d. In the above description, the optical element 71a only needs to be replaced with the optical element 71e, the optical element 71b only needs to be replaced with the optical element 71d, and the direction F1 only needs to be replaced with the direction F2. The above-described features are similar in the direction F corresponding to the optical element 71 for any other (or all) optical element 71 arranged to overlap a position away from the center of the light receiving region 20C in plan view.

Note that, in the optical element 71c arranged so as to overlap the vicinity of the center (image height center) of the light receiving region 20C, the plurality of structures 72 having the same widths is evenly arranged along the directions F1 and F2.

### Manufacturing Method for Photodetection Device

Hereinafter, a method for manufacturing the photodetection device 1 will be described. First, a substrate including the wiring layer 30 to the multilayer film filter 60 is prepared using a known method. Then, a silicon nitride film, which is a material constituting the structures 72, is formed on the exposed surface of the multilayer film filter 60. Thereafter, the structures 72 are formed using a known lithography technique and etching technique.

### Main Effects of Second Embodiment

Hereinafter, main effects of the second embodiment will be described. Effects similar to those of the photodetection device 1 according to the first embodiment described above can also be achieved with the photodetection device 1 according to the second embodiment. More specifically, effects similar to those of the photodetection device 1 according to the first embodiment described above can be obtained in both the pixel 3 near the center of the image height and the pixel 3 at a position with a high image height.

Hereinafter, the effects of the pixel 3 at the position where the image height is high will be described in more detail. The photodetection device 1 according to the second embodiment of the present technology includes the optical elements 71 provided integrally with the semiconductor layer 20 and the multilayer film filter 60 on the side opposite to the semiconductor layer 20 side of the multilayer film filter 60 and provided at a position overlapping the photoelectric conversion regions 20a in plan view, in which the optical elements 71 each include a plurality of structures 72 arranged at intervals in the width direction in plan view, and in the first optical element which is one of the optical elements 71 arranged to overlap the photoelectric conversion region 20a at a position away from the center of arrangement in an array among the photoelectric conversion regions 20a arranged in the array, the structures 72 are arranged at least along a direction from a portion close to an edge of the arrangement in the array of the first optical element toward a portion close to the center, and the density occupied by the structures 72 in the first optical element in plan view is higher in a portion of the first optical element close to the center of the arrangement in the array than in a portion close to the edge. Thus, even in a case where the main light beam is obliquely incident on the photodetection device 1 at a position where the image height is high, the traveling direction of the main light beam L1 can be deflected by the optical element 71 so as to approach the Z direction. Therefore, in a case where the deflected main light beam is reflected in the photoelectric conversion region 20a and re-incident on the multilayer film filter 60 after passing through the multilayer film filter 60, the amount of light passing through the multilayer film filter 60 in the re-incident light can be suppressed. Thus, even at a position where the image height is high, the amount of light that re-transmits through the multilayer film filter 60 and escapes to the outside of the multilayer film filter 60 can be suppressed, so that flare can be suppressed. Furthermore, this makes it possible to suppress reduction in the amount of light reflected by the multilayer film filter 60 toward the photoelectric conversion region 20a side, and to suppress reduction in the amount of light returning to the photoelectric conversion region 20a. Thus, it is possible to suppress a decrease in the optical path length of the incident light in the photoelectric conversion region 20a, and it is possible to suppress a decrease in quantum efficiency (QE). More specifically, the amount of light reflected by the multilayer film filter 60 toward the photoelectric conversion region 20a side can be increased, and the amount of light returning to the photoelectric conversion region 20a can be increased. Thus, the optical path length of the incident light in the photoelectric conversion region 20a can be increased, and the quantum efficiency (QE) can be increased. Therefore, it is possible to suppress a decrease in sensitivity of the photodetection device 1.

Note that, in the photodetection device 1 according to the second embodiment described above, as illustrated in FIG. 15, the insulating film 70a having a refractive index smaller than that of the structures 72 may be interposed between the structures 72 and the multilayer film filter 60, or as illustrated in FIG. 17B, the insulating film 70a need not be interposed between the structures 72 and the multilayer film filter 60. In a case where it is not interposed, the structures 72 are provided on the insulating film 64 illustrated in FIG. 6.

### Modifications of Second Embodiment

In the description below, modifications of the second embodiment are explained.

### Modification 1

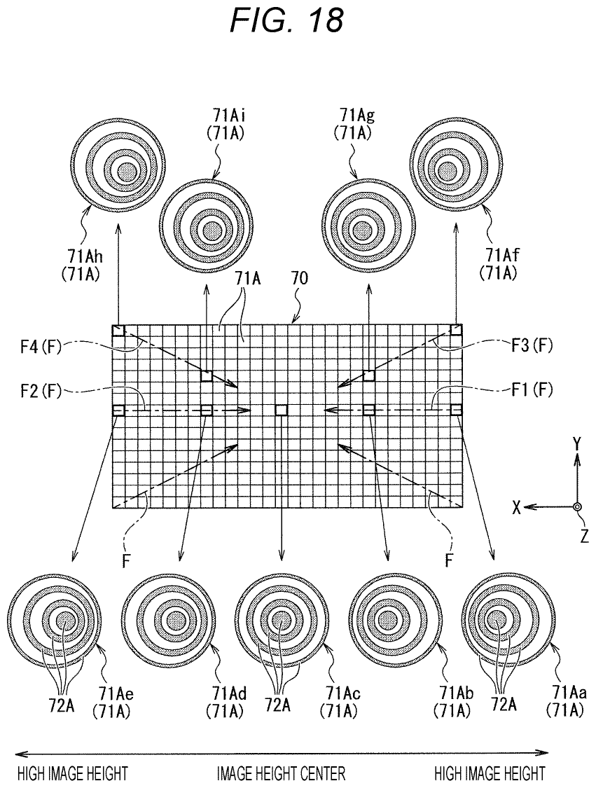

In the photodetection device 1 according to the second embodiment, one structure 72 included in one optical element 71 linearly extends in the longitudinal direction (direction intersecting the width direction) in plan view, but the present technology is not limited thereto. In Modification 1 of the second embodiment illustrated in FIG. 18, one structure 72A included in one optical element 71A is continuous (connected) in the longitudinal direction.

The optical element layer 70 is formed by arranging a plurality of optical elements 71A in a two-dimensional array. FIG. 18 illustrates some of the plurality of optical elements 71A included in the optical element layer 70 in an enlarged manner. More specifically, optical elements 71Aa to 71Ai are illustrated in an enlarged manner. Note that, in a case where the optical elements 71Aa to 71Ai are not distinguished, they are simply referred to as optical elements 71A. The optical element 71Ac is disposed so as to overlap the vicinity of the center of the light receiving region 20C. The optical elements 71Aa and 71Ab are arranged along the direction F1, and the optical elements 71Ad and 71Ae are arranged along the direction F2. Furthermore, the optical elements 71Af and 71Ag are arranged along the direction F3, and the optical elements 71Ah and 71Ai are arranged along the direction F4. The optical elements 71Aa, 71Ab, and 71Ad to 71Ai are optical elements (first optical elements) disposed so as to overlap a position away from the center of the light receiving region 20C in plan view.

One optical element 71A has a plurality of structures 72A. One structure 72A is an annular body having continuous ends in the longitudinal direction (direction intersecting the width direction). More specifically, one structure 72A is an annular body having a circular outer edge and a circular inner edge in plan view. Hereinafter, the structures 72A of the optical element 71Ac (third optical element) arranged so as to overlap the vicinity of the center of the light receiving region 20C will be described as an example. The optical element 71Ac includes three annular structures 72A having different diameters, and further includes one circular structure 72A provided at the center of the annular structures 72A. The plurality of structures 72A included in the optical element 71Ac is provided so that centers of the rings and the circle coincide with each other without overlapping each other in plan view. Another annular structure 72A is provided so as to surround one annular structure 72A in plan view. Then, the annular structures 72A are provided so as to surround the circular structure 72A in plan view. The structures 72A are arranged at intervals in the width direction in plan view.

Since the optical element 71Ac includes the annular structures 72A as described above, the optical element functions as a lens that condenses the incident main light beam toward the center of the photoelectric conversion region 20a. In the present modification, since the refractive index radially decreases from the center toward the edge of the optical element 71Ac in plan view, although not illustrated, the main light beam is deflected so that the wavefront P is convex along the Z direction. More specifically, the main light beam is deflected so that the wavefront P is convex toward the side opposite to the multilayer film filter 60 side of the optical element 71. In other words, the main light beam is deflected so that the wavefront P is convex toward the upstream side in the traveling direction. Thus, the width of the wavefront P gradually decreases in the course of traveling of the main light beam, and the main light beam is condensed toward the center of the photoelectric conversion region 20a. Thus, the optical element 71c can function as a convex lens.

Next, one optical element 71A (first optical element) arranged so as to overlap a position away from the center of the light receiving region 20C in plan view will be described using, for example, the optical element 71Aa as an example. The optical element 71Aa is different from the optical element 71Ac in that the positions of the centers of the annular and circular structures 72A do not coincide with each other, and the structures 72A are arranged along a direction (direction F1) from a portion of the optical element 71Aa close to the edge toward a portion close to the center of the light receiving region 20C. Then, the structures 72A are arranged at least along the direction from the portion of the optical element 71Aa close to the edge of the light receiving region 20C toward the portion close to the center with a space therebetween in the width direction in plan view.

The density occupied by the structures 72A in the optical element 71Aa in plan view is higher in a portion of the optical element 71Aa close to the center of the light receiving region 20C than in the portion close to the edge. More specifically, the density occupied by the structures 72A in the optical element 71Aa in plan view gradually increases from the portion of the optical element 71Aa close to the edge of the light receiving region 20C toward the portion close to the center (along the direction F1). With such a configuration, the optical element 71Aa can deflect the traveling direction of obliquely incident main light beam L1 so as to approach the Z direction. Note that the characteristics of the optical element 71Aa as described above are similar for the other optical element 71A arranged so as to overlap the position away from the center of the light receiving region 20C in plan view.

Note that gradually increasing the density occupied by the structures 72A in the one optical element 71Aa in plan view along the direction F1 is not limited thereto, and for example, in the one optical element 71Aa, it can be implemented by arranging the centers of the annular and circular structures 72A densely along the direction (direction F1) from the portion of the optical element 71Aa close to the edge of the light receiving region 20C to the portion close to the center. Furthermore, since the optical element 71Aa includes the annular structures 72A as described above, similarly to the optical element 71Ac, the optical element 71Aa can function as a convex lens that condenses the incident main light beam toward the center of the photoelectric conversion region 20a.

Furthermore, the features as described above are the same for the optical element 71A (second optical element, for example, optical element 71Ab) arranged so as to overlap a position closer to the center of the light receiving region 20C than the optical element 71Aa (first optical element). However, when comparing the optical element 71Aa and the optical element 71Ab, in plan view, the density occupied by the structures 72A in the portion of the optical element 71Aa close to the edge (center) of the light receiving region 20C is higher than the density occupied by the structures 72A in the portion of the optical element 71Ab close to the center of the light receiving region 20C. That is, the optical element 71A disposed so as to overlap a position closer to the edge of the light receiving region 20C in plan view has a higher density occupied by the structures 72A in a portion closer to the center of the light receiving region 20C. Then, the optical element 71A disposed so as to overlap a position closer to the center of the light receiving region 20C in plan view has a lower density occupied by the structures 72A in the portion closer to the center of the light receiving region 20C. This can be implemented by arranging the center along the direction F1 of the annular and circular structures 72A more sparsely in a portion of the optical element 71Ab close to the center of the light receiving region 20C than in a portion of the optical element 71Aa close to the center of the light receiving region 20C.

Main effects of Modification 1 of the second embodiment will be described below. Effects similar to those of the photodetection device 1 according to the second embodiment described above can also be obtained with the photodetection device 1 according to Modification 1 of the second embodiment.

Furthermore, since the photodetection device 1 according to Modification 1 of the second embodiment of the present technology includes the annular structures 72A, the refractive index changes radially, and the main light beam is deflected so that the wavefront P becomes convex. Thus, the width of the wavefront P gradually decreases in the course of traveling of the main light beam, and the main light beam is condensed toward the center of the photoelectric conversion region 20a. Thus, the sensitivity of the photodetection device 1 is improved.

### Modification 2

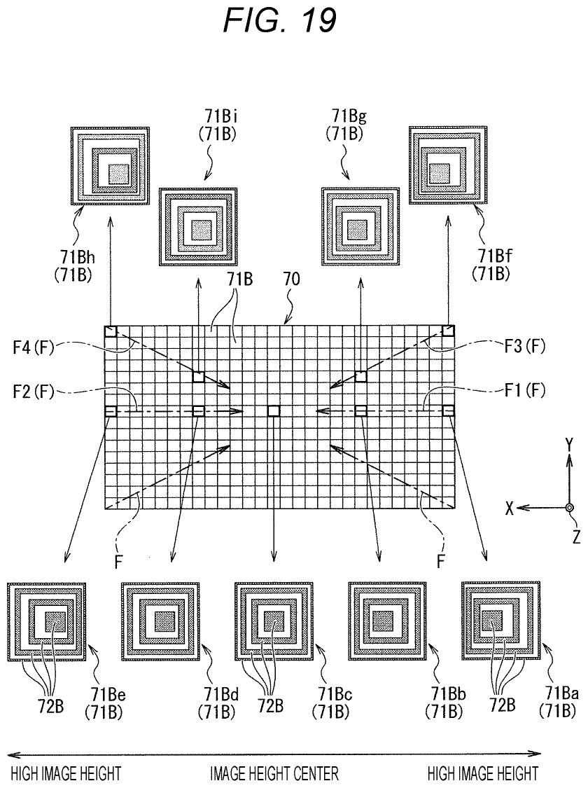

In the photodetection device 1 according to the second embodiment, one structure 72 included in one optical element 71 linearly extends in the longitudinal direction (direction intersecting the width direction) in plan view, but the present technology is not limited thereto. In Modification 2 of the second embodiment illustrated in FIG. 19, one structure 72B included in one optical element 71B is continuous in the longitudinal direction.

Furthermore, in Modification 1 of the second embodiment, one structure 72A is an annular body having a circular outer edge and a circular inner edge in plan view, but the present technology is not limited thereto. In Modification 2 of the second embodiment illustrated in FIG. 19, one structure 72B is a rectangular annular body having a rectangular outer edge and a rectangular inner edge in plan view.

The optical element layer 70 is formed by arranging a plurality of optical elements 71B in a two-dimensional array. FIG. 19 illustrates some of the plurality of optical elements 71B included in the optical element layer 70 in an enlarged manner. More specifically, the optical elements 71Ba to 71Bi are illustrated in an enlarged manner. Note that, in a case where the optical elements 71Ba to 71Bi are not distinguished, they are simply referred to as optical elements 71B. The optical element 71Bc is disposed so as to overlap the vicinity of the center of the light receiving region 20C. The optical elements 71Ba and 71Bb are arranged along the direction F1, and the optical elements 71Bd and 71Be are arranged along the direction F2. Furthermore, the optical elements 71Bf and 71Bg are arranged along the direction F3, and the optical elements 71Bh and 71Bi are arranged along the direction F4. The optical elements 71Ba, 71Bb, and 71Bd to 71Bi are optical elements (first optical elements) arranged so as to overlap a position away from the center of the light receiving region 20C in plan view.

One optical element 71B has a plurality of structures 72B. One structure 72B is an annular body in which the longitudinal direction (direction intersecting the width direction) is continuous. More specifically, one structure 72B is a rectangular annular body having a rectangular outer edge and a rectangular inner edge in plan view. Note that, in FIG. 19, the structure 72B has a square shape, but is not limited thereto, and may have a rectangular shape. Hereinafter, the structures 72B of the optical element 71Bc (third optical element) arranged so as to overlap the vicinity of the center of the light receiving region 20C will be described as an example. The optical element 71Bc includes three annular structures 72B having different dimensions, and further includes one rectangular structure 72B provided at the center of the annular structures 72B. The plurality of structures 72B included in the optical element 71Bc is provided so that centers of the annular body and the rectangle coincide with each other without overlapping each other in plan view. Another annular structure 72B is provided so as to surround one annular structure 72B in plan view. Then, the annular structures 72B are provided so as to surround the rectangular structure 72B in plan view. The structures 72B are arranged at intervals in the width direction in plan view. Since the optical element 71Bc includes the annular structures 72B as described above, the optical element functions as a lens that condenses the incident main light beam toward the center of the photoelectric conversion region 20a as in the case of Modification 1 of the second embodiment.

Next, one optical element 71B (first optical element) arranged so as to overlap a position away from the center of the light receiving region 20C in plan view will be described using, for example, the optical element 71Ba as an example. The optical element 71Ba is different from the optical element 71Bc in that the positions of the centers of the annular and rectangular structures 72B do not coincide with each other, and the structures 72B are arranged along a direction (direction F1) from a portion of the optical element 71Ba close to the edge toward a portion close to the center of the light receiving region 20C. Then, the structures 72B are arranged at least along the direction from the portion of the optical element 71Ba close to the edge of the light receiving region 20C toward the portion close to the center with a space therebetween in the width direction in plan view.

The density occupied by the structures 72B in the optical element 71Ba in plan view is higher in a portion of the optical element 71Ba close to the center of the light receiving region 20C than in the portion close to the edge. More specifically, the density occupied by the structures 72B in the optical element 71Ba in plan view gradually increases from the portion of the optical element 71Ba close to the edge of the light receiving region 20C toward the portion close to the center (along the direction F1). With such a configuration, the optical element 71Ba can deflect the traveling direction of obliquely incident main light beam L1 so as to approach the Z direction. Note that the characteristics as described above are similar for the other optical element 71B arranged so as to overlap the position away from the center of the light receiving region 20C in plan view.

Note that gradually increasing the density occupied by the structures 72B in the one optical element 71Ba in plan view along the direction F1 is not limited thereto, and for example, in the one optical element 71Ba, it can be implemented by arranging the centers of the annular and rectangular structures 72B densely along the direction (direction F1) from the portion of the optical element 71Ba close to the edge of the light receiving region 20C to the portion close to the center. Furthermore, since the optical element 71Ba includes the annular structures 72B as described above, similarly to the optical element 71Bc, the optical element 71Ba can function as a convex lens that condenses the incident main light beam toward the center of the photoelectric conversion region 20a.

Furthermore, the features as described above are the same for the optical element 71B (second optical element, for example, the optical element 71Bb) arranged so as to overlap a position closer to the center of the light receiving region 20C than the optical element 71Ba (first optical element). However, when comparing the optical element 71Ba and the optical element 71Bb, in plan view, the density occupied by the structure 72B in the portion of the optical element 71Ba close to the edge (center) of the light receiving region 20C is higher than the density occupied by the structure 72B in the portion of the optical element 71Bb close to the center of the light receiving region 20C. That is, the optical element 71B disposed so as to overlap a position closer to the edge of the light receiving region 20C in plan view has a higher density occupied by the structures 72B in a portion closer to the center of the light receiving region 20C. Then, the optical element 71B disposed so as to overlap a position closer to the center of the light receiving region 20C in plan view has a lower density occupied by the structures 72B in the portion closer to the center of the light receiving region 20C. This can be implemented by arranging the center along the direction F1 of the annular and rectangular structures 72B more sparsely in a portion of the optical element 71Bb close to the center of the light receiving region 20C than in a portion of the optical element 71Ba close to the center of the light receiving region 20C.

Main effects of Modification 2 of the second embodiment will be described below. Effects similar to those of the photodetection device 1 according to the second embodiment described above can also be obtained with the photodetection device 1 according to Modification 2 of the second embodiment. Furthermore, effects similar to those of the photodetection device 1 according to Modification 1 of the second embodiment described above can also be obtained with the photodetection device 1 according to Modification 2 of the second embodiment.

### Modification 3

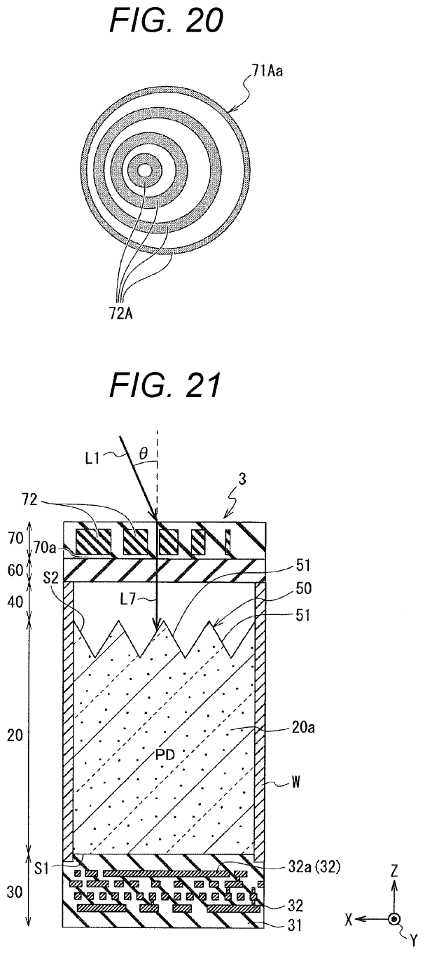

In Modification 1 of the second embodiment, one optical element 71A has an annular and circular structures 72A, but the present technology is not limited thereto. In Modification 3 of the second embodiment illustrated in FIG. 20, one optical element 71A may include only an annular structure 72A.

Effects similar to those of the photodetection device 1 according to the second embodiment of the present technology can also be obtained with the photodetection device 1 according to Modification 3 of the second embodiment of the present technology. Furthermore, effects similar to those of the photodetection device 1 according to Modification 1 of the second embodiment of the present technology can also be obtained with the photodetection device 1 according to Modification 3 of the second embodiment of the present technology.

Note that, although illustration is omitted, also in Modification 2 of the second embodiment, similarly, one optical element 71B may have only an annular structure 72B.

### Modification 4

The photodetection device 1 according to the second embodiment includes the microlens OCL, but in Modification 4 of the second embodiment illustrated in FIG. 21, the photodetection device 1 does not include the microlens OCL. Furthermore, in Modification 4 of the second embodiment, a material having a refractive index lower than that of the material constituting the structure 72 occupies a space between the structures 72 in the optical element 71.

Effects similar to those of the photodetection device 1 according to the second embodiment described above can also be obtained with the photodetection device 1 according to Modification 4 of the second embodiment.

### Modification 5

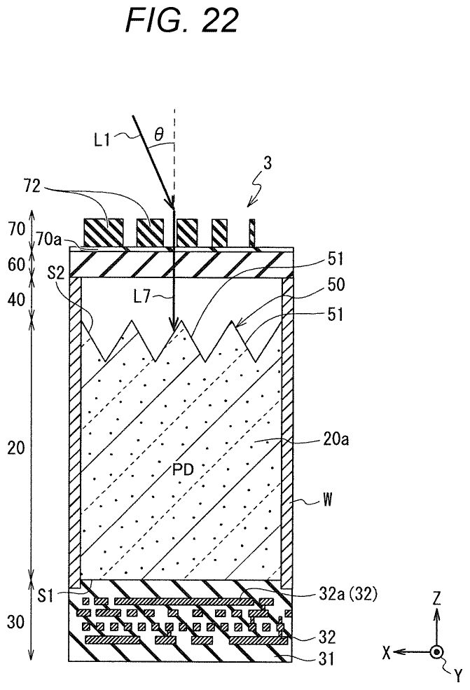

The photodetection device 1 according to the second embodiment includes the microlens OCL, but in Modification 5 of the second embodiment illustrated in FIG. 22, the photodetection device 1 does not include the microlens OCL. Furthermore, in Modification 5 of the second embodiment, air occupies a space between the structures 72 in the optical element 71.

Effects similar to those of the photodetection device 1 according to the second embodiment described above can also be obtained with the photodetection device 1 according to Modification 5 of the second embodiment.

### Modification 6

In the photodetection device 1 according to the second embodiment, one structure 72 included in one optical element 71 has a plate shape and extends linearly in the longitudinal direction in plan view, but the present technology is not limited thereto. In Modification 6 of the second embodiment, although not illustrated, one structure 72 may have a pillar shape extending in the Z direction. Note that the cross-sectional shape of the pillar in the horizontal direction is not particularly limited.

Effects similar to those of the photodetection device 1 according to the second embodiment of the present technology can also be obtained with the photodetection device 1 according to Modification 6 of the second embodiment of the present technology.

### Third Embodiment

In the third embodiment, a configuration example of an electronic device will be described. As depicted in FIG. 23, a distance image device 201 as an electronic device includes an optical system 202, a sensor chip 2X, an image processing circuit 203, a monitor 204, and a memory 205. The distance image device 201 can acquire a distance image according to a distance to a subject by receiving light (modulated light or pulsed light) projected from the light source device 211 toward the subject and reflected on a surface of the subject.

The optical system 202 includes one or more optical lenses, guides image light (incident light) from a subject to the sensor chip 2X, and forms an image on a light receiving surface (sensor unit) of the sensor chip 2X.

As the sensor chip 2X, the semiconductor chip 2 on which the photodetection device 1 according to the first embodiment described above is mounted is applied, and a distance signal indicating a distance obtained from a light reception signal (APD OUT) output from the sensor chip 2X is supplied to the image processing circuit 203.

The image processing circuit 203 performs image processing of constructing a distance image on the basis of the distance signal supplied from the sensor chip 2X, and the distance image (image data) obtained by the image processing is supplied to and displayed on the monitor 204 or supplied to and stored (recorded) in the memory 205.

In the distance image device 201 configured as described above, it is possible to generate a distance image in which flare is suppressed by applying the sensor chip 2X described above.

Note that, although the semiconductor chip 2 on which the photodetection device 1 according to the first embodiment of the present technology is mounted is applied as the sensor chip 2X, the semiconductor chip 2 on which the photodetection device 1 according to any one of the modifications of the first embodiment, the second embodiment, and the modifications of the second embodiment is mounted may be applied, and further, the semiconductor chip 2 on which the photodetection device 1 according to a combination of at least two of the first embodiment, the modifications of the first embodiment, the second embodiment, and the second embodiment is mounted may be applied.

### Use Example of Image Sensor

The sensor chip 2X (image sensor) described above can be used in various cases for sensing light such as visible light, infrared light, ultraviolet light, and X-ray as described below, for example.
A device that captures an image, provided for viewing purposes, such as a digital camera and a portable device with a camera function
A device for traffic purpose such as an in-vehicle sensor that captures images of the front, rear, surroundings, interior, and the like of an automobile, a monitoring camera for monitoring traveling vehicles and roads, and a ranging sensor that measures a distance between vehicles and the like for safe driving such as automatic stop, recognition of a driver's condition, and the like
A device used for home electric appliances such as a television, a refrigerator, and an air conditioner in order to capture an image of a gesture of a user and perform device operation according to the gesture
A device used for medical and health care such as an endoscope and a device that performs angiography by receiving infrared light
A device used for security such as a security monitoring camera and an individual authentication camera
A device used for beauty care such as a skin measuring instrument for capturing images of skin and a microscope for capturing images of the scalp
A device used for sport such as an action camera or a wearable camera for sports applications or the like
A device provided for agricultural purposes, such as a camera for monitoring conditions of fields and crops.

### Other Embodiments

As described above, the present technology has been described by way of the first to third embodiments, but it should not be understood that the description and drawings constituting a part of this disclosure limit the present technology. Various alternative embodiments, examples, and operation techniques will be apparent to those skilled in the art from this disclosure.

For example, the technical ideas described in the first to third embodiments may be combined with each other. For example, although the uneven shape 50 according to the modification of the first embodiment described above has various shapes, various combinations according to the respective technical ideas, such as application of such a technical idea to the photodetection device 1 described in the second embodiment and the modification thereof, are possible.

Furthermore, the present technology can be applied to all kinds of photodetection devices including not only the above-described solid-state imaging device as an image sensor but also a ranging sensor also called a time of flight (ToF) sensor that measures distances, and the like. The ranging sensor is a sensor that emits irradiation light toward an object, detects reflected light that is the irradiation light reflected off a surface of the object, and calculates a distance to the object on the basis of a flight time from the emission of the irradiation light to the reception of the reflected light. As a structure of the ranging sensor, structures such as the uneven shape 50, the multilayer film filter 60, and the optical element 71 described above can be adopted.

Furthermore, the photodetection device 1 described above is a solid-state imaging device that captures an infrared image, but may be a solid-state imaging device that captures a color image. In this case, the multilayer film filter 60 has a configuration designed to transmit any color of red, blue, and green for each pixel 3.

Furthermore, the photodetection device 1 may be a stacked CMOS image sensor (CIS) in which two or more semiconductor substrates are stacked on top of each other. In that case, at least one of the logic circuit 13 or the readout circuit 15 may be provided on a substrate different from the semiconductor substrate on which the photoelectric conversion regions 20a are provided among these semiconductor substrates.

Furthermore, the materials mentioned as the materials forming the components described above may contain additives, impurities, or the like, for example.

As described above, it is needless to say that the present technology includes various embodiments and the like that are not described herein. Therefore, the technical scope of the present technology is defined only by the matters used to define the inventions disclosed in the claims considered appropriate from the above description.

Furthermore, the effects described herein are mere examples and are not restrictive, and there may be additional effects.

Note that the present technology may have the following configurations.

(1)

A photodetection device including:
a semiconductor layer in which one surface is a light incident surface and another surface is an element formation surface, the semiconductor layer including a plurality of photoelectric conversion regions arranged in an array along a row direction and a column direction perpendicular to a thickness direction; and
a multilayer film filter provided integrally with the semiconductor layer on a side of the light incident surface of the semiconductor layer and provided at a position overlapping the photoelectric conversion regions, in which
a side of the light incident surface of the photoelectric conversion regions has an uneven shape, and
the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.
   (2)

The photodetection device according to (1), in which the uneven shape has a surface inclined with respect to the thickness direction of the semiconductor layer.

(3)

The photodetection device according to (1), in which the uneven shape has a groove recessed in the thickness direction of the semiconductor layer.

(4)

The photodetection device according to any one of (1) to (3), in which a half-value width of the first wavelength band is equal to or less than 100 nm.

(5)

The photodetection device according to any one of (1) to (3), in which a half-value width of the first wavelength band is equal to or less than 50 nm.

(6)

The photodetection device according to any one of (1) to (3), in which a half-value width of the first wavelength band is equal to or less than 40 nm.

(7)

The photodetection device according to any one of (1) to (3), in which a half-value width of the first wavelength band is equal to or less than 30 nm.

(8)

The photodetection device according to any one of (1) to (7), in which
the first wavelength band is a band corresponding to near-infrared light, and the multilayer film filter is a band pass filter that transmits near-infrared light.
   (9)

The photodetection device according to any one of (1) to (8), including
a separation wall extending along the thickness direction and partitioning between the photoelectric conversion regions adjacent to each other, in which
an end of the separation wall on the side of the light incident surface is connected to the multilayer film filter.
   (10)

The photodetection device according to (9), in which the separation wall is made by metal.

(11)

The photodetection device according to (9), in which the separation wall is made by a material having a smaller refractive index than the semiconductor layer.

(12)

The photodetection device according to any one of (1) to (11), further including:
optical elements provided integrally with the semiconductor layer and the multilayer film filter on a side opposite to a side of the semiconductor layer of the multilayer film filter and provided at a position overlapping the photoelectric conversion regions in a plan view, in which
the optical elements each include a plurality of structures arranged at intervals in a width direction in plan view, and
in a first optical element which is one of the optical elements arranged to overlap the photoelectric conversion region at a position away from a center of arrangement in an array among the photoelectric conversion regions arranged in the array, the structures are arranged at least along a direction from a portion close to an edge of the arrangement in the array of the first optical element toward a portion close to the center, and
a density occupied by the structures in the first optical element in plan view is higher in a portion of the first optical element close to the center of the arrangement in the array than in a portion close to the edge.
   (13)

An electronic device including a photodetection device and an optical system that forms an image of image light from a subject on the photodetection device, in which
the photodetection device includes:
a semiconductor layer in which one surface is a light incident surface and another surface is an element formation surface, the semiconductor layer including a plurality of photoelectric conversion regions arranged in an array along a row direction and a column direction perpendicular to a thickness direction; and
a multilayer film filter provided integrally with the semiconductor layer on a side of the light incident surface of the semiconductor layer and provided at a position overlapping the photoelectric conversion regions, in which
a side of the light incident surface of the photoelectric conversion regions has an uneven shape, and
the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1 Photodetection device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
Readout 15 Circuit
20 Semiconductor layer
20a Photoelectric conversion region
20b Isolation region
20C Light receiving region
30 Wiring layer
32a Reflection layer
40 Insulating layer
50 Uneven shape
51 Recess
52, 52a, 52b, 52c, 52d Inclined surface
60 Multilayer film filter
61, 61a, 61b, 61c High refractive index layer
62, 62a, 62b Low refractive index layer
63, 64 Insulating film
65 Stacked structure
70 Optical element layer
71 Optical element
72 Structure
2X Sensor chip
202 Optical system (optical lens)
203 Image processing circuit
204 Monitor
205 Memory
211 Light source device

1. A photodetection device comprising:
a semiconductor layer in which one surface is a light incident surface and another surface is an element formation surface, the semiconductor layer including a plurality of photoelectric conversion regions arranged in an array along a row direction and a column direction perpendicular to a thickness direction; and
a multilayer film filter provided integrally with the semiconductor layer on a side of the light incident surface of the semiconductor layer and provided at a position overlapping the photoelectric conversion regions, wherein
a side of the light incident surface of the photoelectric conversion regions has an uneven shape, and
the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.

2. The photodetection device according to claim 1, wherein the uneven shape has a surface inclined with respect to the thickness direction of the semiconductor layer.

3. The photodetection device according to claim 1, wherein the uneven shape has a groove recessed in the thickness direction of the semiconductor layer.

4. The photodetection device according to claim 1, wherein a half-value width of the first wavelength band is equal to or less than 100 nm.

5. The photodetection device according to claim 1, wherein a half-value width of the first wavelength band is equal to or less than 50 nm.

6. The photodetection device according to claim 1, wherein a half-value width of the first wavelength band is equal to or less than 40 nm.

7. The photodetection device according to claim 1, wherein a half-value width of the first wavelength band is equal to or less than 30 nm.

8. The photodetection device according to claim 1, wherein
the first wavelength band is a band corresponding to near-infrared light, and
the multilayer film filter is a band pass filter that transmits near-infrared light.

9. The photodetection device according to claim 1, further comprising:
a separation wall extending along the thickness direction and partitioning between the photoelectric conversion regions adjacent to each other, wherein
an end of the separation wall on the side of the light incident surface is connected to the multilayer film filter.

10. The photodetection device according to claim 9, wherein the separation wall is made by metal.

11. The photodetection device according to claim 9, wherein the separation wall is made by a material having a smaller refractive index than the semiconductor layer.

12. The photodetection device according to claim 1, further comprising:
optical elements provided integrally with the semiconductor layer and the multilayer film filter on a side opposite to a side of the semiconductor layer of the multilayer film filter and provided at a position overlapping the photoelectric conversion regions in a plan view, wherein
the optical elements each include a plurality of structures arranged at intervals in a width direction in plan view, and
in a first optical element which is one of the optical elements arranged to overlap the photoelectric conversion region at a position away from a center of arrangement in an array among the photoelectric conversion regions arranged in the array, the structures are arranged at least along a direction from a portion close to an edge of the arrangement in the array of the first optical element toward a portion close to the center, and
a density occupied by the structures in the first optical element in plan view is higher in a portion of the first optical element close to the center of the arrangement in the array than in a portion close to the edge.

13. An electronic device comprising a photodetection device and an optical system that forms an image of image light from a subject on the photodetection device, wherein
the photodetection device includes:
a semiconductor layer in which one surface is a light incident surface and another surface is an element formation surface, the semiconductor layer including a plurality of photoelectric conversion regions arranged in an array along a row direction and a column direction perpendicular to a thickness direction; and
a multilayer film filter provided integrally with the semiconductor layer on a side of the light incident surface of the semiconductor layer and provided at a position overlapping the photoelectric conversion regions,
a side of the light incident surface of the photoelectric conversion regions has an uneven shape, and
the multilayer film filter has a stacked structure in which a high refractive index layer and a low refractive index layer are alternately stacked, and is capable of transmitting light in a first wavelength band at a higher transmittance than light in other wavelength bands among light incident along the thickness direction.
